(19) United States
(12) Patent Application Publication
(10) Pub. No.: US 2024/0027897 A1
(43) Pub. Date: Jan. 25, 2024

(54) LAMINATE AND MANUFACTURING METHOD OF LAMINATE

(71) Applicant: FUJIFILM Corporation, Tokyo (JP)

(72) Inventors: Yohei ARITOSHI, Shizuoka (JP); Kentaro TOYOOKA, Shizuoka (JP)

(73) Assignee: FUJIFILM Corporation, Tokyo (JP)

(21) Appl. No.: 18/475,635

(22) Filed: Sep. 27, 2023

Related U.S. Application Data
(63) Continuation of application No. PCT/JP22/04743, filed on Feb. 7, 2022.

(30) Foreign Application Priority Data
Mar. 30, 2021 (JP) 2021-058108

(51) Int. Cl. G03F 7/00; G03F 7/32; G03F 7/038

(52) U.S. Cl. CPC G03F 7/0005; G03F 7/32; G03F 7/038

(57) ABSTRACT

Provided are a laminate including a base material and a resin pattern, in which, in a case where, based on a depth direction analysis of the resin pattern performed along a direction from the resin pattern toward the base material, an intensity of at least one component selected from the group consisting of a sodium ion and a potassium ion, which is detected on a surface of the resin pattern, is defined as 100%, a depth of presence of the at least one component selected from the group consisting of a sodium ion and a potassium ion in the resin pattern is 0.3 μm to 3.0 μm, the depth of presence being defined by a distance from the surface of the resin pattern to a point where the intensity of the at least one component selected from the group consisting of a sodium ion and a potassium ion first reaches 90%; and a manufacturing method of the laminate.

### CROSS-REFERENCE TO RELATED APPLICATIONS

This application is a continuation of International Application No. PCT/JP2022/004743, filed on Feb. 7, 2022, which claims priority from Japanese Patent Application No. 2021-058108, filed on Mar. 30, 2021. The entire disclosure of each of the above applications is incorporated herein by reference.

### BACKGROUND OF THE INVENTION

### 1. Field of the Invention

The present disclosure relates to a laminate and a manufacturing method of a laminate.

### 2. Description of the Related Art

A resin pattern formed of a photosensitive composition is used, for example, as a protective film for an electrode such as an electrode for a touch panel, and a protective film against a chemical reaction such as etching. In the former application, a cured substance of the photosensitive composition is preferably used.

For example, WO2013/084886A discloses a method of forming a resin cured film pattern.

Specifically, WO2013/084886A discloses a method of forming a resin cured film pattern, the method including a first step of forming, on a base material, a photosensitive layer formed of a photosensitive resin composition which contains a binder polymer with a carboxyl group having an acid value of 75 mgKOH/g or more, a photopolymerizable compound, and a photopolymerization initiator, the photosensitive layer having a thickness of 10 μm or less; a second step of curing a predetermined portion of the photosensitive layer by irradiation with actinic ray; and a third step of removing portions other than the predetermined portion of the photosensitive layer to form a cured film pattern of the predetermined portion of the photosensitive layer, in which the photosensitive resin composition contains, as the photopolymerization initiator, an oxime ester compound and/or a phosphine oxide compound.

### SUMMARY OF THE INVENTION

For example, it is preferable that the resin pattern used as the protective film is less susceptible to damage such as scratch. On the other hand, according to the related art, it has been difficult to achieve both resistance of the resin pattern to physical action of causing damage such as scratch and edge quality of the resin pattern. The edge quality is defined by factors such as, for example, shape, dimensions, and surface properties of edge of the resin pattern. In particular, as the edge quality, suppression of a phenomenon that the edge of the resin pattern is lifted from the base material (it means that the edge of the resin pattern separates from the base material; hereinafter, may be referred to as “edge lift”) has been required.

An object of an embodiment of the present disclosure is to provide a laminate including a resin pattern which has excellent scratch resistance, in which the edge lift is prevented or reduced. An object of another embodiment of the present disclosure is to provide a manufacturing method of a laminate including a resin pattern which has excellent scratch resistance, in which the edge lift is prevented or reduced.

The present disclosure includes the following aspects.
<1> A laminate comprising:
a base material; and
a resin pattern,
in which, in a case where, based on a depth direction analysis of the resin pattern performed along a direction from the resin pattern toward the base material, an intensity of at least one component selected from the group consisting of a sodium ion and a potassium ion, which is detected on a surface of the resin pattern, is defined as 100%, a depth of presence of the at least one component selected from the group consisting of a sodium ion and a potassium ion in the resin pattern is 0.3 μm to 3.0 μm, the depth of presence being defined by a distance from the surface of the resin pattern to a point where the intensity of the at least one component selected from the group consisting of a sodium ion and a potassium ion first reaches 90%.
<2> The laminate according to <1>,
in which a ratio of the depth of presence to a thickness of the resin pattern is 0.1 to 0.9.
<3> The laminate according to <1> or <2>,
in which the resin pattern is a cured substance of a photosensitive composition.
<4> The laminate according to <3>,
in which the photosensitive composition contains a polymerizable compound and a polymerization initiator.
<5> The laminate according to <3> or <4>,
in which the photosensitive composition contains a polymer.
<6> The laminate according to <5>,
in which the polymer has a polymerizable group.
<7> The laminate according to any one of <1> to <6>, further comprising:
a transparent electrode between the base material and the resin pattern.
<8> The laminate according to any one of <1> to <7>,
in which the laminate is a touch panel.
<9> A manufacturing method of a laminate, comprising, in the following order:
disposing a photosensitive layer on a base material;
exposing the photosensitive layer in a patterned manner;
removing an exposed portion or a non-exposed portion of the photosensitive layer using a developer containing at least one component selected from the group consisting of a sodium ion and a potassium ion to form a resin pattern;
washing the resin pattern with water; and
allowing the base material and the resin pattern to stand,
in which, in a case where, based on a depth direction analysis of the resin pattern after allowing the base material and the resin pattern to stand, which is performed along a direction from the resin pattern toward the base material, an intensity of at least one component selected from the group consisting of a sodium ion and a potassium ion, which is detected on a surface of the resin pattern, is defined as 100%, a depth of presence of the at least one component selected from the group consisting of a sodium ion and a potassium ion in the resin pattern is 0.3 μm to 3.0 μm, the depth of presence being defined by a distance from the surface of the resin pattern to a point where the intensity of the at least one component selected from the group consisting of a sodium ion and a potassium ion first reaches 90%.

According to the embodiment of the present disclosure, there is provided a laminate including a resin pattern which has excellent scratch resistance, in which the edge lift is prevented or reduced. According to another embodiment of the present disclosure, there is provided a manufacturing method of a laminate including a resin pattern which has excellent scratch resistance, in which the edge lift is prevented or reduced.

### BRIEF DESCRIPTION OF THE DRAWINGS

FIG. 1 is a schematic cross-sectional view showing a structure of a laminate according to one embodiment.

FIG. 2 is a schematic cross-sectional view showing a structure of a laminate according to another embodiment.

### DESCRIPTION OF THE PREFERRED EMBODIMENTS

Hereinafter, embodiments of the present disclosure will be described in detail. The present disclosure is not limited to the following embodiments. The following embodiments may be modified as appropriate within the scope of the purposes of the present disclosure.

In the present disclosure, the numerical ranges shown using “to” indicate ranges including the numerical values described before and after “to” as the minimum value and the maximum value. In the numerical range described stepwise in the present disclosure, the upper limit value or the lower limit value described in a certain numerical range may be replaced with the upper limit value or the lower limit value of another numerical range described stepwise. In addition, regarding the numerical range described in the present disclosure, an upper limit value or a lower limit value described in a numerical value may be replaced with a value described in Examples.

In the present disclosure, in a case where a plurality of substances corresponding to each component in a composition is present, the amount of each component in the composition means the total amount of the plurality of substances present in the composition, unless otherwise specified.

In the present disclosure, the term “step” includes not only an independent step but also a step that cannot be clearly distinguished from other steps, as long as the intended purpose of the step is achieved.

In the present disclosure, “transparent” means that an average transmittance of visible light having a wavelength of 400 nm to 700 nm is 80% or more. An average transmittance is measured using a spectrophotometer (for example, a spectrophotometer U-3310 manufactured by Hitachi, Ltd.).

In the present disclosure, “(meth)acrylic” means acrylic, methacrylic, or both acrylic and methacrylic.

In the present disclosure, “(meth)acrylate” means acrylate, methacrylate, or both acrylate and methacrylate.

In the present disclosure, “(meth)acryloyl” means acryloyl, methacryloyl, or both acryloyl and methacryloyl.

In the present disclosure, a notation of a group (atomic group) in which “substituted” and “unsubstituted” are not described includes a group not having a substituent and a group having a substituent. For example, an “alkyl group” not only includes an alkyl group not having a substituent (unsubstituted alkyl group), but also includes an alkyl group having a substituent (substituted alkyl group).

In the present disclosure, unless specified otherwise, “exposure” denotes not only exposure using light but also drawing using a corpuscular beam such as an electron beam or an ion beam. In addition, generally, examples of light used for the exposure include actinic rays or radiation such as a bright line spectrum of a mercury lamp, far ultraviolet rays typified by an excimer laser, extreme ultraviolet rays (EUV light), X-rays, and actinic ray (active energy ray) such as electron beam.

A chemical structural formula in the present disclosure may be described by a simplified structural formula in which hydrogen atoms are omitted.

In the present disclosure, “% by mass” has the same definition as that for “% by weight”, and “part by mass” has the same definition as that for “part by weight”.

In the present disclosure, a combination of two or more preferred aspects is a more preferred aspect.

The weight-average molecular weight (Mw) and the number-average molecular weight (Mn) in the present disclosure are molecular weights in terms of polystyrene used as a standard substance, which are detected by using a solvent tetrahydrofuran (THF), a differential refractometer, and a gel permeation chromatography (GPC) analyzer using TSKgel GMHxL, TSKgel G4000HxL, and TSKgel G2000HxL (all product names manufactured by Tosoh Corporation) as columns, unless otherwise specified.

In the present disclosure, unless otherwise specified, a numerical value added to each constitutional unit of a polymer represents mol %.

In the present disclosure, unless otherwise specified, a refractive index is a value measured by using an ellipsometer at a wavelength of 550 nm.

In the present disclosure, unless otherwise specified, a hue is a value measured by using a colorimeter (CR-221, manufactured by Konica Minolta, Inc.).

In the present disclosure, “alkali-soluble” means that the solubility in 100 g of aqueous solution of 1% by mass sodium carbonate at a liquid temperature of 22° C. is 0.1 g or more.

In the present disclosure, “solid content” means all components excluding a solvent.

<Laminate>

The laminate according to the embodiment of the present disclosure includes a base material and a resin pattern. Furthermore, in a case where, based on a depth direction analysis of the resin pattern performed along a direction from the resin pattern toward the base material, an intensity of at least one component selected from the group consisting of a sodium ion and a potassium ion, which is detected on a surface of the resin pattern, is defined as 100%, a depth of presence of the at least one component selected from the group consisting of a sodium ion and a potassium ion in the resin pattern is 0.3 μm to 3.0 μm, the depth of presence being defined by a distance from the surface of the resin pattern to a point where the intensity of the at least one component selected from the group consisting of a sodium ion and a potassium ion first reaches 90%. Hereinafter, the “at least one component selected from the group consisting of a sodium ion and a potassium ion” may be referred to as “specific component”. As will be described later, the depth of presence of the specific component in the resin pattern is measured by a depth direction analysis using time-of-flight secondary ion mass spectrometry (TOF-SIMS), and is expressed by a distance “the surface of the resin pattern” to “a point where the intensity of the at least one component selected from the group consisting of a sodium ion and a potassium ion reaches a reference value”. According to a study on improving scratch resistance of the resin pattern and reducing edge lift, although the causal relationship is not clear, the results suggest that a degree of permeation of components of the developer into the resin pattern affects the scratch resistance of the resin pattern and the edge lift. The developer is a chemical used for development. The sodium ion and the potassium ion are known as representative components of the developer. As a result of further studies, it has been confirmed that, in a case where the depth of presence of the specific component in the resin pattern is 0.3 μm to 3.0 μm, the scratch resistance of the resin pattern is improved and the edge lift is reduced. Therefore, according to the embodiment of the present disclosure, there is provided a laminate including a resin pattern which has excellent scratch resistance, in which the edge lift is prevented or reduced.

(Base Material)

The laminate according to one embodiment of the present disclosure includes a base material. Examples of the base material include a resin base material, a glass base material, and a semiconductor base material. The base material is preferably a resin base material. Examples of the resin base material include a cycloolefin polymer film, a polypropylene film, a polyethylene terephthalate film (for example, a biaxial stretching polyethylene terephthalate film), a polymethylmethacrylate film, a cellulose triacetate film, a polystyrene film, a polyimide film, and a polycarbonate film. The base material preferably contains a polymer, more preferably contains at least one selected from the group consisting of a cycloolefin polymer and a polyimide, and still more preferably contains a cycloolefin polymer.

A thickness of the base material is preferably 5 μm to 200 μm, and more preferably 10 μm to 100 μm. The thickness of the base material is represented by an arithmetic average of thicknesses at five points, measured by cross-sectional observation using a scanning electron microscope (SEM).

A preferred aspect of the base material is described in paragraph of WO2018/155193A. The contents of the above-described document are incorporated in the present specification by reference.

(Resin Pattern)

The laminate according to the embodiment of the present disclosure includes a resin pattern. The resin pattern may be disposed in a state of being in contact with the base material. Other constituent elements may be disposed between the base material and the resin pattern.

A shape, width, and spacing of the resin pattern are determined, for example, according to an application. The width of the resin pattern is preferably in a range of 5 μm to 1,000 μm. The spacing of the resin pattern is preferably in a range of 5 μm to 1,000 μm.

From the viewpoint of strength, a thickness of the resin pattern is preferably 0.5 μm or more, more preferably 1 μm or more, still more preferably 3 μm or more, and particularly preferably 5 μm or more. The upper limit of the thickness of the resin pattern may be 40 μm, 30 μm, 20 μm, or 10 μm. The thickness of the resin pattern is represented by an arithmetic average of thicknesses at five points, measured by cross-sectional observation using a scanning electron microscope (SEM).

The depth of presence of the at least one component selected from the group consisting of a sodium ion and a potassium ion in the resin pattern is 0.3 μm to 3.0 μm. In the present disclosure, the aspect of “depth of presence of the at least one component selected from the group consisting of a sodium ion and a potassium ion in the resin pattern is 0.3 μm to 3.0 μm” includes the following (1) to (3). However, in the present disclosure, a depth of presence of a component of the sodium ion or the potassium ion may be specified. That is, in the present disclosure, the depth of presence of the sodium ion in the resin pattern may be 0.3 μm to 3.0 μm, or the depth of presence of the potassium ion in the resin pattern may be 0.3 μm to 3.0 μm.
(1) the depth of presence of the sodium ion in the resin pattern is 0.3 μm or more and 3.0 μm or less, and the depth of presence of the potassium ion in the resin pattern is 0.3 μm or more and 3.0 μm or less.
(2) the depth of presence of the sodium ion in the resin pattern is 0.3 μm or more and 3.0 μm or less, and the depth of presence of the potassium ion in the resin pattern is less than μm or more than 3.0 μm.
(3) the depth of presence of the sodium ion in the resin pattern is less than 0.3 μm or more than 3.0 μm, and the depth of presence of the potassium ion in the resin pattern is 0.3 μm or more and 3.0 μm or less.

From the viewpoint of improving the scratch resistance, the depth of presence of the at least one component selected from the group consisting of a sodium ion and a potassium ion in the resin pattern is preferably 0.5 μm or more, more preferably 1.0 μm or more, and still more preferably 1.5 μm or more. From the viewpoint of reducing the edge lift, the depth of presence of the at least one component selected from the group consisting of a sodium ion and a potassium ion in the resin pattern is preferably 2.8 μm or less, more preferably 2.5 μm or less, and still more preferably 2.2 μm or less.

The depth of presence of the at least one component selected from the group consisting of a sodium ion and a potassium ion in the resin pattern is measured by a depth direction analysis using time-of-flight secondary ion mass spectrometry (TOF-SIMS). First, using a known determination device used for TOF-SIMS (for example, SWISS manufactured by IONTOF GmbH and Ar⁺ cluster sputtering gun), distribution of a target component (that is, the sodium ion or the potassium ion) in a depth direction of the resin pattern is measured. The depth direction analysis is performed along a direction from the resin pattern toward the base material. Specifically, the sodium ion or the potassium ion is detected by TOF-SIMS while sputtering the measurement target with the Ar⁺ cluster sputtering gun. Next, on the assumption that an intensity of the target component detected on the surface of the resin pattern is 100%, a sputtering time when the intensity of the target component first reaches 90% is converted to a depth (that is, a distance from the surface of the resin pattern to the point where the intensity of the target component first reaches 90%) based on a sputtering rate. The above-described “depth” is measured at any three points which are points where the edge lift does not occur in the pattern, are separated by 10 μm or more in a plane direction of the base material from the point where the edge lift occurs, and are separated by 100 μm or more from each other, and then an arithmetic average value of three measured values is defined as the “depth of presence”. In a case where another layer (for example, optical clear adhesive (OCA)) is attached to the resin pattern, the sodium ion or the potassium ion is detected by TOF-SIMS while sputtering the layer as well. In the measurement result of TOF-SIMS, an interface between the resin pattern and another layer is determined based on the thickness of each layer, the sputtering rate, and the components detected in each layer. For example, at an interface between the resin pattern and another layer which does not contain the sodium ion or the potassium ion, since the peak of sodium ion or potassium ion rises, a portion where the peak of sodium ion or potassium ion rises can be regarded as the surface of the resin pattern.

The depth of presence of the specific component (that is, the at least one component selected from the group consisting of a sodium ion and a potassium ion) in the resin pattern is adjusted, for example, according to manufacturing conditions of the resin pattern. For example, as described in the section of “Manufacturing method of laminate” later, in a case where a developer containing the specific component is used in the process of manufacturing the resin pattern, the depth of presence of the specific component in the resin pattern changes according to a degree of permeation of components of the developer into the resin pattern. For example, in a case where the degree of permeation of the components of the developer into the resin pattern is large, the depth of presence of the specific component in the resin pattern is large. On the other hand, in a case where the degree of permeation of the components of the developer into the resin pattern is small, the depth of presence of the specific component in the resin pattern is small. As described in the section of “Manufacturing method of laminate” later, the degree of permeation of the components of the developer into the resin pattern is adjusted by, for example, conditions of development (for example, temperature of the developer and treatment time), conditions of washing (for example, water temperature and treatment time), and standing time after washing. However, the method of adjusting the depth of presence of the specific component in the resin pattern is not limited to the above-described specific examples.

From the viewpoint of scratch resistance, edge quality (particularly, reduction of edge lift), and strength, a ratio of the depth of presence of the specific component in the resin pattern to the thickness of the resin pattern is preferably 0.1 to 0.9, more preferably 0.2 to 0.7, and still more preferably 0.3 to 0.5. From the viewpoint of scratch resistance, edge quality (particularly, reduction of edge lift), and strength, an absolute value between the thickness of the resin pattern and the depth of presence of the specific component in the resin pattern is preferably 0.5 μm to μm, more preferably 1 μm to 6 μm, and still more preferably 2 μm to 4 μm.

A moisture permeability of the resin pattern at a thickness of 40 μm is preferably 500 g/(m² 24 hr) or less, more preferably 300 g/(m² 24 hr) or less, and still more preferably 100 g/(m² 24 hr) or less. Examples of a specific preferred numerical value include 80 g/(m² 24 hr), 150 g/(m² 24 hr), and 220 g/(m² 24 hr). The moisture permeability is measured according to “JIS Z 0208 (1976)” (cup method). It is preferable that the above-described moisture permeability is as described above under any test conditions of temperature 40° C. and humidity 90%, temperature 65° C. and humidity 90%, or temperature 80° C. and humidity 95%.

Examples of the component of the resin pattern include a polymer. Examples of the polymer include polymers described as the component of the photosensitive layer in the section of “Manufacturing method of laminate” later. Examples of the polymer also include polymerizable compounds described as the component of the photosensitive layer in the section of “Manufacturing method of laminate” later.

The resin pattern is preferably a cured substance of a photosensitive composition. The photosensitive composition preferably contains a polymer. The photosensitive composition also preferably contains a polymerizable compound and a polymerization initiator. The photosensitive composition also preferably contains a polymer, a polymerizable compound, and a polymerization initiator. The polymer preferably has a polymerizable group and more preferably has a radically polymerizable group. Aspects of the photosensitive composition are described in the section of “Manufacturing method of laminate” later. A method of curing the photosensitive composition is determined, for example, depending on the component of the photosensitive composition. Examples of a preferred method of curing the photosensitive composition include exposure described in the section of “Manufacturing method of laminate” later.

(Other Constituent Elements)

The laminate according to the embodiment of the present disclosure may further include other constituent elements as necessary. The types, arrangements, and numbers of the other constituent elements are determined, for example, according to a purpose. Examples of the other constituent elements include a transparent electrode and a lead wire.

It is preferable that the laminate according to the embodiment of the present disclosure includes a transparent electrode. Specifically, it is preferable that the laminate according to the embodiment of the present disclosure includes a transparent electrode between the base material and the resin pattern. That is, it is preferable that the laminate according to the embodiment of the present disclosure includes the base material, the transparent electrode, and the resin pattern in this order. It is also preferable that the laminate according to the embodiment of the present disclosure includes the resin pattern, the transparent electrode, the base material, the transparent electrode, and the resin pattern in this order. Examples of a component of the transparent electrode include a metal oxide. Examples of the metal oxide include indium tin oxide (ITO) and indium zinc oxide (IZO). The transparent electrode may be configured of a fine metal wire such as a metal nanowire. Examples of the fine metal wire include a fine silver wire and a fine copper wire. The transparent electrode may be configured of a metal mesh. A silver conductive material such as a silver mesh and a silver nanowire is preferable. The transparent electrode may be a transparent electrode pattern.

It is preferable that the laminate according to the embodiment of the present disclosure includes a lead wire. The lead wire is preferably disposed between the base material and the resin pattern. In a case where the laminate includes the transparent electrode and the lead wire, it is preferable that the lead wire is electrically connected to the transparent electrode. Examples of a component of the lead wire include metal. Examples of the metal include gold, silver, copper, molybdenum, aluminum, titanium, chromium, zinc, and manganese. The metal may be an alloy. As a component of the lead wire, copper, molybdenum, aluminum, or titanium is preferable, copper is more preferable.

Examples of the other constituent elements also include a refractive index adjusting layer. Examples of the refractive index adjusting layer include refractive index adjusting layers described as the constituent element of the transfer film in the section of “Manufacturing method of laminate” later.

(Structure)

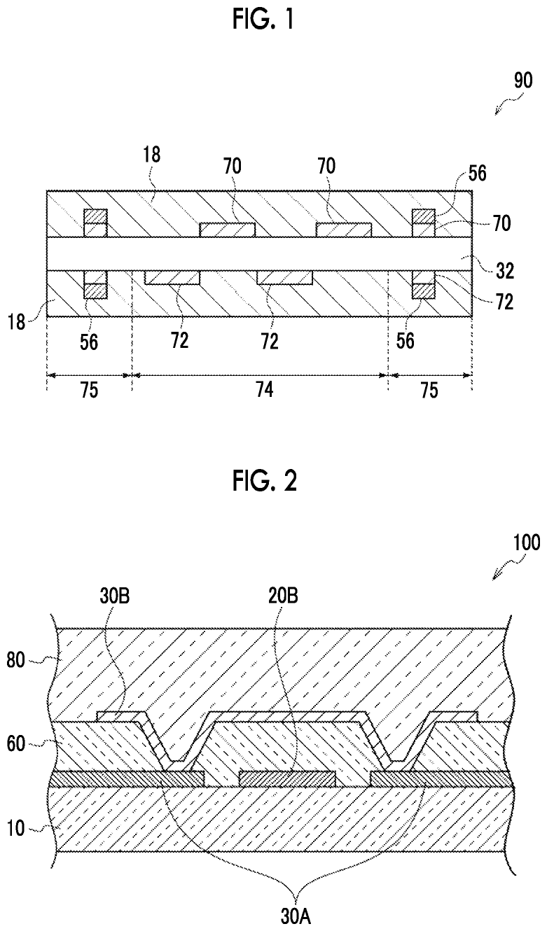

A structure of the laminate will be described with reference to FIGS. 1 and 2. FIG. 1 is a schematic cross-sectional view showing a structure of a laminate according to one embodiment. FIG. 2 is a schematic cross-sectional view showing a structure of the laminate according to another embodiment. However, the structure of the laminate is not limited to the structure shown in each figure.

A laminate 90 shown in FIG. 1 includes an image display region 74 and an image non-display region 75 (that is, a frame portion). The laminate 90 includes an electrode for a touch panel on both surfaces of a base material 32. Specifically, the laminate 90 includes a first metal conductive material 70 on one surface of the base material 32 and includes a second metal conductive material 72 on the other surface of the base material 32. In the laminate 90, a lead wire 56 is connected to the first metal conductive material 70 and the second metal conductive material 72, respectively. Examples of the lead wire 56 include a copper wire and a silver wire. The lead wire 56 is surrounded by a resin pattern 18, and the first metal conductive material 70 or the second metal conductive material 72. In the laminate 90, the resin pattern 18 is formed on one surface of the base material 32 so as to cover the first metal conductive material 70 and the lead wire 56, and the resin pattern 18 is formed on the other surface of the base material 32 so as to cover the second metal conductive material 72 and the lead wire 56.

A laminate 100 shown in FIG. 2 includes a base material 10, a first wiring part 20B, a second island-shaped electrode portion 30A, a second wiring part 30B, a resin pattern 60, and a transparent layer 80. The first wiring parts 20B are alternately arranged with a first island-shaped electrode portion (not shown) from the front to the back of FIG. 2, and two adjacent first island-shaped electrode portions (not shown) are electrically connected through the first wiring part 20B. Two adjacent second island-shaped electrode portions 30A are electrically connected through the second wiring part 30B. The first island-shaped electrode portion 20B and the second island-shaped electrode portion 30A are covered with the resin pattern 60. Further, the resin pattern 60 and the second wiring part 30B are covered with the transparent layer 80. Examples of the transparent layer 80 include OCA.

(Application)

The laminate according to the embodiment of the present disclosure is adopted to, for example, an application such as a touch panel. The laminate according to the embodiment of the present disclosure is preferably a touch panel is preferable, and more preferably a capacitive touch panel. In the laminate adopted as the touch panel, it is preferable that the resin pattern functions as a protective film for an electrode for a touch panel or a wiring line for a touch panel.

The laminate according to the embodiment of the present disclosure can be used for precision nanofabrication by photolithography. In the application of precision nanofabrication by photolithography, it is preferable that the resin pattern functions as an etching resist. In a case where the resin pattern is used as an etching resist, it is preferable that the laminate according to the embodiment of the present disclosure includes a conductive layer between the base material and the resin pattern. Examples of the conductive layer include a metal layer, a metal oxide layer, and a layer including a fine metal wire. Examples of materials of the metal layer, the metal oxide layer, and the layer including a fine metal wire include substances described in the section of “Other constituent elements” above. In a case where the resin pattern is used as an etching resist, it is preferable that the laminate is formed through a step of forming a photosensitive layer on a conductive layer which has been disposed on a base material; a step of exposing the photosensitive layer in a patterned manner, a step of removing unnecessary portions from the exposed photosensitive layer, and a step of removing the conductive layer in a portion where the photosensitive layer has been removed to obtain a conductive pattern.

The laminate according to the embodiment of the present disclosure can be adopted for various wiring formation applications for semiconductor packages, printed circuit boards, and sensor boards; conductive films such as electromagnetic shielding materials, and film heaters; and formations of structures in liquid crystal sealing materials, micromachines, and microelectronics fields.

However, the applications of the laminate according to the embodiment of the present disclosure are not limited to the above-described specific examples.

<Manufacturing Method of Laminate>

Next, a manufacturing method of a laminate according to the embodiment of the present disclosure will be described. As long as a desired laminate is obtained, the manufacturing method of a laminate is not limited. The manufacturing method of a laminate according to the embodiment of the present disclosure preferably includes, in the following order: a step of disposing a photosensitive layer on a base material (hereinafter, referred to as “disposing step”); exposing the photosensitive layer in a patterned manner (hereinafter, referred to as “exposing step”); removing an exposed portion or a non-exposed portion of the photosensitive layer using a developer containing at least one component selected from the group consisting of a sodium ion and a potassium ion to form a resin pattern (hereinafter, referred to as “developing step”); washing the resin pattern with water (hereinafter, referred to as “washing step”; and allowing the base material and the resin pattern to stand (hereinafter, referred to as “standing step”), in which, in a case where, based on a depth direction analysis of the resin pattern after allowing the base material and the resin pattern to stand, which is performed along a direction from the resin pattern toward the base material, an intensity of at least one component selected from the group consisting of a sodium ion and a potassium ion, which is detected on a surface of the resin pattern, is defined as 100%, a depth of presence of the at least one component selected from the group consisting of a sodium ion and a potassium ion in the resin pattern is 0.3 μm to 3.0 μm, the depth of presence being defined by a distance from the surface of the resin pattern to a point where the intensity of the at least one component selected from the group consisting of a sodium ion and a potassium ion first reaches 90%. In the related art such as the method forming a resin cured film pattern, disclosed in WO2013/084886A, no detailed study has been made on a process aimed at adjusting the depth of presence of the specific component in the resin pattern. On the other hand, the series of developing step, washing step, and standing step in the present disclosure affects the depth of presence of the specific component (that is, the at least one component selected from the group consisting of a sodium ion and a potassium ion) in the resin pattern. In particular, the standing step greatly contributes to the purpose of adjusting the depth of presence of the specific component in the resin pattern to a specific range. For example, a degree of permeation of components of the developer into the resin pattern varies depending on conditions of the developing step, conditions of the washing step, and conditions of the standing step, and the depth of presence of the specific component in the resin pattern is adjusted to 0.3 μm to 3.0 μm. Therefore, according to the embodiment of the present disclosure, there is provided a manufacturing method of a laminate including a resin pattern which has excellent scratch resistance, in which the edge lift is prevented or reduced.

(Disposing Step)

In the disposing step, a photosensitive layer is disposed on a base material. In the disposing step, the photosensitive layer may be disposed in a state of being in contact with the base material. Other constituent elements may be disposed between the base material and the photosensitive layer. For example, the manufacturing method of a laminate including the base material, the transparent electrode, and the resin pattern in this order preferably includes, before the disposing step, preparing a substrate including the base material and the transparent electrode in this order.

Aspects of the base material are described in the section of “Laminate” above. Preferred aspects of the base material are the same as the preferred aspects of the base material described in the section of “Laminate” above.

As the photosensitive layer, a negative tone photosensitive layer is preferable. The negative tone photosensitive layer has a property that solubility of an exposed portion in the developer is lower than that of a non-exposed portion.

A thickness of the photosensitive layer is determined, for example, according to a thickness of a target resin pattern. The preferred aspects of the thickness of the resin pattern, described in the section of “Laminate” above, are adopted to preferred aspects of the thickness of the photosensitive layer. The thickness of the photosensitive layer may be 30 μm or less. From the viewpoint of improving developability, the thickness of the photosensitive layer is preferably 20 μm or less, more preferably 15 μm or less, still more preferably 10 μm or less, and particularly preferably 5.0 μm or less. From the viewpoint of improving the strength of the resin pattern, a thickness of the photosensitive layer is preferably 0.60 μm or more and more preferably 1.5 μm or more. The thickness of the photosensitive layer is represented by an arithmetic average of thicknesses at five points, measured by cross-sectional observation using a scanning electron microscope (SEM).

A refractive index of the photosensitive layer is preferably 1.41 to 1.59 and more preferably 1.47 to 1.56.

The photosensitive layer is preferably achromatic. In CIE1976 (L*, a*, b*) color space measured with the total reflection (incidence angle: 8°, light source: D-65 (visual field: 2°)), the L* value is preferably 10 to 90, the a* value is preferably −1.0 to 1.0, and the b* value is preferably −1.0 to 1.0.

From the viewpoint of rust preventive property of electrode or wiring line and reliability of the laminate, a visible light transmittance of the photosensitive layer per 1.0 μm thickness is preferably 80% or more, more preferably 90% or more, and most preferably 95% or more. As the visible light transmittance, it is preferable that an average transmittance at a wavelength of 400 nm to 800 nm, the minimum value of the transmittance at a wavelength of 400 nm to 800 nm, and a transmittance at a wavelength of 400 nm are all 80% or more. Examples of a preferred value of the transmittance include 87%, 92%, and 98%.

From the viewpoint of suppressing residue during development, a dissolution rate of the photosensitive layer in a 1.0% by mass sodium carbonate aqueous solution is preferably 0.01 μm/sec or more, more preferably 0.10 μm/sec or more, and still more preferably 0.20 μm/sec or more. From the viewpoint of edge shape of the pattern, a dissolution rate of the photosensitive layer in a 1.0% by mass sodium carbonate aqueous solution is preferably 5.0 μm/sec or less, more preferably 4.0 μm/sec or less, and still more preferably 3.0 μm/sec or less. Examples of a specific preferred numerical value include 1.8 μm/sec, 1.0 μm/sec, and 0.7 μm/sec. The dissolution rate of the photosensitive layer in a 1.0% by mass sodium carbonate aqueous solution is measured by the following method. A photosensitive layer (within a thickness of 1.0 μm to 10 μm) from which the solvent has been sufficiently removed is subjected to a shower development with a 1.0% by mass sodium carbonate aqueous solution at 25° C. until the photosensitive layer is dissolved completely. However, the upper limit of shower development time is 2 minutes. A shower nozzle used in the development is ¼ MiNJJX030PP manufactured by H.IKEUCHI Co., Ltd. A spraying pressure of the shower is set to 0.08 MPa. A shower flow rate per unit time is set to 1,800 mL/min. The dissolution rate is obtained by dividing the thickness of the photosensitive layer by the time required for the photosensitive layer to dissolve completely. In a case where the photosensitive layer is not dissolved completely in 2 minutes, the dissolution rate of the photosensitive layer is calculated in the same manner as above, from the amount of change in film thickness up to 2 minutes.

From the viewpoint of improving pattern formability, a swelling ratio of the photosensitive layer after exposure with respect to a 1.0% by mass sodium carbonate aqueous solution is preferably 100% or less, more preferably 50% or less, and still more preferably 30% or less. Examples of a specific preferred numerical value include 4%, 13%, and 25%. The swelling ratio of the photosensitive layer after exposure with respect to a 1.0% by mass sodium carbonate aqueous solution is measured by the following method. A photosensitive layer (within a thickness of 1.0 μm to 10 μm) from which the solvent has been sufficiently removed is exposed at an exposure amount of 500 mJ/cm² (i-ray measurement) with an ultra-high pressure mercury lamp. The photosensitive layer is immersed in a 1.0% by mass sodium carbonate aqueous solution at 25° C., and the thickness of the photosensitive layer is measured after 30 seconds. A rate at which the thickness of the photosensitive layer after immersion increases with respect to the thickness of the photosensitive layer before immersion is calculated.

From the viewpoint of pattern formability, the number of foreign substances having a diameter of 1.0 μm or more in the photosensitive layer is preferably 10 pieces/mm² or less, and more preferably 5 pieces/mm² or less. Examples of a specific preferred numerical value include 0 pieces/mm², 1 pieces/mm², 4 pieces/mm², and 8 pieces/mm². The number of foreign substances is measured by the following method. Any 5 regions (1 mm×1 mm) on a surface of the photosensitive layer are visually observed from a normal direction of the surface of the photosensitive layer with an optical microscope, the number of foreign substances having a diameter of 1.0 μm or more in each region is measured, and the values are arithmetically averaged to calculate the number of foreign substances.

From the viewpoint of suppressing generation of aggregates during development, a haze of a solution obtained by dissolving 1.0 cm³ of the photosensitive layer in 1.0 liter (L) of a 1.0% by mass sodium carbonate aqueous solution at 30° C. is preferably 60% or less, more preferably 30% or less, still more preferably 10% or less, and particularly preferably 1% or less. Examples of a specific preferred numerical value include 0.4%, 1%, 9%, and 24%. The haze is measured by the following method. First, a 1.0% by mass sodium carbonate aqueous solution is prepared, and a liquid temperature is adjusted to 30° C. 1.0 cm³ of the photosensitive layer is added to 1.0 L of the sodium carbonate aqueous solution. The solution is stirred at for 4 hours, being careful not to mix air bubbles. After stirring, the haze of the solution in which the photosensitive layer is dissolved is measured. The haze is measured using a haze meter (product name “NDH4000”, manufactured by Nippon Denshoku Industries Co., Ltd.), a liquid measuring unit, and a liquid measuring cell having an optical path length of 20 mm.

Examples of a component of the photosensitive layer include a polymer, a polymerizable compound, a polymerization initiator, a heterocyclic compound, an aliphatic thiol compound, a thermal crosslinking compound, a surfactant, a polymerization inhibitor, and a hydrogen donating compound.

The photosensitive layer preferably contains a polymer. Hereinafter, the polymer will be described.

Examples of the polymer include a (meth)acrylic resin, a styrene resin, an epoxy resin, an amide resin, an amido epoxy resin, an alkyd resin, a phenol resin, an ester resin, a urethane resin, an epoxy acrylate resin obtained by a reaction of an epoxy resin and a (meth)acrylic acid, and acid-modified epoxy acrylate resin obtained by a reaction of an epoxy acrylate resin and acid anhydride.

From the viewpoint of excellent alkali developability and film formability, examples of one suitable aspect of the polymer include a (meth)acrylic resin. In the present disclosure, the (meth)acrylic resin means a resin having a constitutional unit derived from a (meth)acrylic compound. A content of the constitutional unit derived from a (meth)acrylic compound is preferably 50% by mass or more, more preferably 70% by mass or more, and still more preferably 90% by mass or more with respect to all constitutional units of the (meth)acrylic resin. The (meth)acrylic resin may be composed of only the constitutional unit derived from a (meth)acrylic compound, or may have a constitutional unit derived from a polymerizable monomer other than the (meth)acrylic compound. That is, the upper limit of the content of the constitutional unit derived from a (meth)acrylic compound is 100% by mass with respect to all constitutional units of the (meth)acrylic resin.

Examples of the (meth)acrylic compound include (meth)acrylic acid, (meth)acrylic acid ester, (meth)acryl amide, and (meth)acrylonitrile.

Examples of the (meth)acrylic acid ester include (meth)acrylic acid alkyl ester, (meth)acrylic acid tetrahydrofurfuryl ester, (meth)acrylic acid dimethylaminoethyl ester, (meth)acrylic acid di ethyl aminoethyl ester, (meth)acrylic acid glycidyl ester, (meth)acrylic acid benzyl ester, 2,2,2-trifluoroethyl (meth)acrylate, and 2,2,3,3-tetrafluoropropyl (meth)acrylate, and (meth)acrylic acid alkyl ester is preferable.

An alkyl group of the (meth)acrylic acid alkyl ester may be linear or branched. Specific examples of the (meth)acrylic acid alkyl ester include methyl (meth)acrylate, ethyl (meth)acrylate, propyl (meth)acrylate, butyl (meth)acrylate, pentyl (meth)acrylate, hexyl (meth)acrylate, heptyl (meth)acrylate, octyl (meth)acrylate, 2-ethylhexyl (meth)acrylate, nonyl (meth)acrylate, decyl (meth)acrylate, undecyl (meth)acrylate, and dodecyl (meth)acrylate. The (meth)acrylic acid ester is preferably (meth)acrylic acid alkyl ester having an alkyl group having 1 to 12 carbon atoms, more preferably (meth)acrylic acid alkyl ester having an alkyl group having 1 to 4 carbon atoms, and still more preferably methyl (meth)acrylate or ethyl (meth)acrylate.

Examples of the (meth)acrylamide include acrylamides such as diacetone acrylamide. The (meth)acrylic resin may have a constitutional unit other than the constitutional unit derived from a (meth)acrylic compound. The polymerizable monomer forming the above-described constitutional unit is not particularly limited as long as it is a compound other than the (meth)acrylic compound, which can be copolymerized with the (meth)acrylic compound, and examples thereof include styrene compounds which may have a substituent at an α-position or an aromatic ring, such as styrene, vinyltoluene, and α-methylstyrene, vinyl alcohol esters such as acrylonitrile and vinyl-n-butyl ether, maleic acid monoesters such as maleic acid, maleic acid anhydride, monomethyl maleate, monoethyl maleate, and monoisopropyl maleate, fumaric acid, cinnamic acid, α-cyanocinnamic acid, itaconic acid, and crotonic acid. These polymerizable monomers may be used alone or in combination of two or more kinds thereof.

In addition, from the viewpoint of improving alkali developability, the (meth)acrylic resin preferably has a constitutional unit having an acid group. Examples of the acid group include a carboxy group, a sulfo group, a phosphoric acid group, and a phosphonic acid group. The (meth)acrylic resin more preferably has a constitutional unit having a carboxy group, and still more preferably has a constitutional unit derived from the above-described (meth)acrylic acid.

From the viewpoint of excellent developability, the content of the constitutional unit having an acid group (preferably, the constitutional unit derived from (meth)acrylic acid) in the (meth)acrylic resin is preferably 10% by mass or more with respect to the total mass of the (meth)acrylic resin. In addition, the upper limit value thereof is not particularly limited, but from the viewpoint of excellent alkali resistance, is preferably 50% by mass or less and more preferably 40% by mass or less.

In addition, it is more preferable that the (meth)acrylic resin has a constitutional unit derived from the above-described (meth)acrylic acid alkyl ester. A content of the constitutional unit derived from (meth)acrylic acid alkyl ester in the (meth)acrylic resin is preferably 50% by mass to 90% by mass, more preferably 60% by mass to 90% by mass, and still more preferably 65% by mass to 90% by mass with respect to all constitutional units of the (meth)acrylic resin.

As the (meth)acrylic resin, a resin having both the constitutional unit derived from (meth)acrylic acid and the constitutional unit derived from (meth)acrylic acid alkyl ester is preferable, and a resin composed only of the constitutional unit derived from (meth)acrylic acid and the constitutional unit derived from (meth)acrylic acid alkyl ester is more preferable. In addition, as the (meth)acrylic resin, an acrylic resin which has a constitutional unit derived from methacrylic acid, a constitutional unit derived from methyl methacrylate, and a constitutional unit derived from ethyl acrylate is also preferable.

The (meth)acrylic resin preferably has at least one selected from the group consisting of a constitutional unit derived from methacrylic acid and a constitutional unit derived from methacrylic acid alkyl ester, and more preferably has both the constitutional unit derived from methacrylic acid and the constitutional unit derived from methacrylic acid alkyl ester. The total content of the constitutional unit derived from methacrylic acid and the constitutional unit derived from methacrylic acid alkyl ester in the (meth)acrylic resin is preferably 40% by mass or more and more preferably 60% by mass or more with respect to all constitutional units of the (meth)acrylic resin. The upper limit thereof is not particularly limited, and may be 100% by mass or less, preferably 80% by mass or less.

It is also preferable that the (meth)acrylic resin has at least one selected from the group consisting of a constitutional unit derived from methacrylic acid and a constitutional unit derived from methacrylic acid alkyl ester, and has at least one selected from the group consisting of a constitutional unit derived from acrylic acid and a constitutional unit derived from acrylic acid alkyl ester. The total content of the constitutional unit derived from methacrylic acid and the constitutional unit derived from methacrylic acid alkyl ester is preferably 60/40 to 80/20 in terms of mass ratio with respect to the total content of the constitutional unit derived from acrylic acid and the constitutional unit derived from acrylic acid alkyl ester.

From the viewpoint of excellent developability of the photosensitive layer, the (meth)acrylic resin preferably has an ester group at the terminal. The terminal portion of the (meth)acrylic resin is composed of a site derived from a polymerization initiator used in the synthesis. The (meth)acrylic resin having an ester group at the terminal can be synthesized by using a polymerization initiator which generates a radical having an ester group.

In addition, examples of other suitable aspects of the polymer include an alkali-soluble resin. From the viewpoint of developability, the polymer is, for example, preferably a polymer having an acid value of 60 mgKOH/g or more. In addition, from the viewpoint that it is easy to form a strong film by thermally crosslinking with a crosslinking component by heating, for example, the polymer is more preferably a resin (so-called a carboxy group-containing resin) having an acid value of 60 mgKOH/g or more and having a carboxy group, and still more preferably a (meth)acrylic resin (so-called a carboxy group-containing (meth)acrylic resin) having an acid value of 60 mgKOH/g or more and having a carboxy group. In a case where the polymer is a resin having a carboxy group, for example, the three-dimensional crosslinking density can be increased by adding a thermal crosslinking compound such as a blocked isocyanate compound and thermally crosslinking. In addition, in a case where the carboxy group of the resin having a carboxy group is anhydrous and hydrophobized, wet heat resistance can be improved.

The carboxy group-containing (meth)acrylic resin having an acid value of 60 mgKOH/g or more is not particularly limited as long as the above-described conditions of acid value are satisfied, and a known (meth)acrylic resin can be appropriately selected. For example, a carboxy group-containing acrylic resin having an acid value of 60 mgKOH/g or more among polymers described in paragraph [0025] of JP2011-095716A, a carboxy group-containing acrylic resin having an acid value of 60 mgKOH/g or more among polymers described in paragraphs [0033] to [0052] of JP2010-237589A, and the like can be preferably used.

Examples of other suitable aspects of the polymer include a styrene-acrylic copolymer. The styrene-acrylic copolymer refers to a resin having a constitutional unit derived from a styrene compound and a constitutional unit derived from a (meth)acrylic compound, and the total content of the constitutional unit derived from a styrene compound and the constitutional unit derived from a (meth)acrylic compound is preferably 30% by mass or more and more preferably 50% by mass or more with respect to all constitutional units of the copolymer. In addition, the content of the constitutional unit derived from a styrene compound is preferably 1% by mass or more, more preferably 5% by mass or more, and still more preferably 5% by mass to 80% by mass with respect to the all constitutional units of the above-described copolymer. In addition, the content of the constitutional unit derived from the above-described (meth)acrylic compound is preferably 5% by mass or more, more preferably 10% by mass or more, and still more preferably 20% by mass to 95% by mass with respect to the all constitutional units of the above-described copolymer.

In one aspect, the polymer preferably has an aromatic ring structure, and more preferably has a constitutional unit having an aromatic ring structure. Examples of a monomer forming the constitutional unit having an aromatic ring structure include a monomer having an aralkyl group, styrene, and a polymerizable styrene derivative (for example, methylstyrene, vinyltoluene, tert-butoxystyrene, acetoxystyrene, 4-vinylbenzoic acid, styrene dimer, and styrene trimer). Among these, a monomer having an aralkyl group or styrene is preferable. Examples of the aralkyl group include a substituted or unsubstituted phenylalkyl group (excluding a benzyl group), and a substituted or unsubstituted benzyl group, and a substituted or unsubstituted benzyl group is preferable.

Examples of a monomer having the phenylalkyl group include phenylethyl (meth)acrylate.

Examples of a monomer having the benzyl group include (meth)acrylates having a benzyl group, such as benzyl (meth)acrylate and chlorobenzyl (meth)acrylate; and vinyl monomers having a benzyl group, such as vinylbenzyl chloride and vinylbenzyl alcohol. Among these, benzyl (meth)acrylate is preferable.

In one aspect, the polymer more preferably has a constitutional unit represented by Formula (S) (constitutional unit derived from styrene).

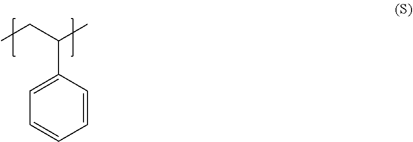

In a case where the polymer has the constitutional unit having an aromatic ring structure, a content of the constitutional unit having an aromatic ring structure is preferably 5% by mass to 90% by mass, more preferably 10% by mass to 70% by mass, and still more preferably 20% by mass to 60% by mass with respect to all constitutional units of the polymer.

The content of the constitutional unit having an aromatic ring structure in the polymer is preferably 5 mol % to 70 mol %, more preferably 10 mol % to 60 mol %, and still more preferably 20 mol % to 60 mol % with respect to all constitutional units of the polymer.

A content of the constitutional unit represented by Formula (S) described above in the polymer is preferably 5 mol % to 70 mol %, more preferably 10 mol % to 60 mol %, still more preferably 20 mol % to 60 mol %, and particularly preferably 20 mol % to 50 mol % with respect to all constitutional units of the polymer.

In the present disclosure, in a case where the content of a “constitutional unit” is defined by a molar ratio, the “constitutional unit” is synonymous with the “monomer unit”. In addition, in the present disclosure, the “monomer unit” may be modified after polymerization by a polymer reaction or the like. The same applies to the following.

In one aspect, the polymer preferably has an aliphatic hydrocarbon ring structure. That is, the polymer preferably has a constitutional unit having an aliphatic hydrocarbon ring structure. The aliphatic hydrocarbon ring structure may be monocyclic or polycyclic. Among these, the polymer more preferably has a ring structure in which two or more aliphatic hydrocarbon rings are fused.

Examples of a ring constituting the aliphatic hydrocarbon ring structure in the constitutional unit having an aliphatic hydrocarbon ring structure include a tricyclodecane ring, a cyclohexane ring, a cyclopentane ring, a norbornane ring, and an isophorone ring. A ring in which two or more aliphatic hydrocarbon rings are fused is preferable, and a tetrahydrodicyclopentadiene ring (tricyclo[5.2.1.0^{2,6}]decane ring) is more preferable.

Examples of a monomer forming the constitutional unit having an aliphatic hydrocarbon ring structure include dicyclopentanyl (meth)acrylate, cyclohexyl (meth)acrylate, and isobornyl (meth)acrylate.

In one aspect, the polymer more preferably has a constitutional unit represented by Formula (Cy), and more preferably has the above-described constitutional unit represented by Formula (S) and the constitutional unit represented by Formula (Cy).

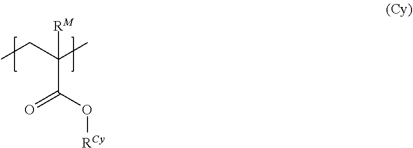

In Formula (Cy), R^{M} represents a hydrogen atom or a methyl group, and R^{Cy} represents a monovalent group having an aliphatic hydrocarbon ring structure.

R^{M} in Formula (Cy) is preferably a methyl group.

R^{Cy} in Formula (Cy) is preferably a monovalent group having an aliphatic hydrocarbon ring structure having 5 to 20 carbon atoms, more preferably a monovalent group having an aliphatic hydrocarbon ring structure having 6 to 16 carbon atoms, and still more preferably a monovalent group having an aliphatic hydrocarbon ring structure having 8 to 14 carbon atoms.

The aliphatic hydrocarbon ring structure in R^{Cy} of Formula (Cy) is preferably a cyclopentane ring structure, a cyclohexane ring structure, a tetrahydrodicyclopentadiene ring structure, a norbornane ring structure, or an isophorone ring structure, more preferably a cyclohexane ring structure or a tetrahydrodicyclopentadiene ring structure, and still more preferably a tetrahydrodicyclopentadiene ring structure.

The aliphatic hydrocarbon ring structure in R^{Cy} of Formula (Cy) is preferably a ring structure in which two or more aliphatic hydrocarbon rings are fused, and more preferably a ring in which two to four aliphatic hydrocarbon rings are fused.

R^{Cy} in Formula (Cy) is preferably a group in which the oxygen atom in —C(═O)O— of Formula (Cy) and the aliphatic hydrocarbon ring structure are directly bonded, that is, an aliphatic hydrocarbon ring group, more preferably a cyclohexyl group or a dicyclopentanyl group, and still more preferably a dicyclopentanyl group.

The polymer may have one constitutional unit having an aliphatic hydrocarbon ring structure alone, or two or more kinds thereof.

In a case where the polymer has the constitutional unit having an aliphatic hydrocarbon ring structure, a content of the constitutional unit having an aliphatic hydrocarbon ring structure is preferably 5% by mass to 90% by mass, more preferably 10% by mass to 80% by mass, and still more preferably 20% by mass to 70% by mass with respect to all constitutional units of the polymer.

The content of the constitutional unit having an aliphatic hydrocarbon ring structure in the polymer is preferably 5 mol % to 70 mol %, more preferably 10 mol % to 60 mol %, and still more preferably 20 mol % to 50 mol % with respect to all constitutional units of the polymer.

The content of the constitutional unit represented by Formula (Cy) described above in the polymer is preferably 5 mol % to 70 mol %, more preferably 10 mol % to 60 mol %, and still more preferably 20 mol % to 50 mol % with respect to all constitutional units of the polymer.

In a case where the polymer includes the constitutional unit having an aromatic ring structure and the constitutional unit having an aliphatic hydrocarbon ring structure, the total content of the constitutional unit having an aromatic ring structure and the constitutional unit having an aliphatic hydrocarbon ring structure is preferably 10% by mass to 90% by mass, more preferably 20% by mass to 80% by mass, and particularly preferably 40% by mass to 75% by mass with respect to all constitutional units of the polymer.

The total content of the constitutional unit having an aromatic ring structure and the constitutional unit having an aliphatic hydrocarbon ring structure in the polymer is preferably 10 mol % to 80 mol %, more preferably 20 mol % to 70 mol %, and still more preferably 40 mol % to 60 mol % with respect to all constitutional units of the polymer.

The total content of the constitutional unit represented by Formula (S) described above and the constitutional unit represented by Formula (Cy) described above in the polymer is preferably 10 mol % to 80 mol %, more preferably 20 mol % to 70 mol %, and still more preferably 40 mol % to 60 mol % with respect to all constitutional units of the polymer.

A molar amount nS of the constitutional unit represented by Formula (S) and a molar amount nCy of the constitutional unit represented by Formula (Cy) in the polymer preferably satisfy the relationship shown in the following expression (SCy), more preferably satisfy the following expression (SCy-1), and still more preferably satisfy the following expression (SCy-2).

0.2<nS/(nS+nCy)<0.8: Expression (SCy)

0.30<nS/(nS+nCy)<0.75: Expression (SCy-1)

0.40<nS/(nS+nCy)<0.70: Expression (SCy-2)

The polymer preferably has a constitutional unit having an acid group. Examples of the acid group include a carboxy group, a sulfo group, a phosphonic acid group, and a phosphoric acid group, and a carboxy group is preferable. As the constitutional unit having an acid group, constitutional units derived from (meth)acrylic acid, which are shown below, is preferable, and a constitutional unit derived from methacrylic acid is more preferable.

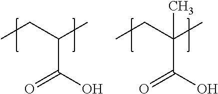

The polymer may have one constitutional unit having an acid group alone, or two or more kinds thereof.

In a case where the polymer has the constitutional unit having an acid group, a content of the constitutional unit having an acid group is preferably 5% by mass to 50% by mass, more preferably 5% by mass to 40% by mass, and still more preferably 10% by mass to 30% by mass with respect to all constitutional units of the polymer.

The content of the constitutional unit having an acid group in the polymer is preferably 5 mol % to 70 mol %, more preferably 10 mol % to 50 mol %, and still more preferably 20 mol % to 40 mol % with respect to all constitutional units of the polymer.

A content of the constitutional unit derived from (meth)acrylic acid in the polymer is preferably 5 mol % to 70 mol %, more preferably 10 mol % to 50 mol %, and still more preferably 20 mol % to 40 mol % with respect to all constitutional units of the polymer.

The polymer preferably has a reactive group, and more preferably has a constitutional unit having a reactive group. As the reactive group, a polymerizable group is preferable, a radically polymerizable group is more preferable, and an ethylenically unsaturated group is still more preferable. In addition, in a case where the polymer has an ethylenically unsaturated group, the polymer preferably has a constitutional unit having an ethylenically unsaturated group in a side chain. In the present disclosure, the “main chain” represents a relatively longest binding chain in a molecule of a polymer compound constituting a resin, and the “side chain” represents an atomic group branched from the main chain. As the ethylenically unsaturated group, an allyl group or a (meth)acryloxy group is more preferable. Examples of the constitutional unit having a reactive group include those shown below, but the constitutional unit having a reactive group is not limited thereto.

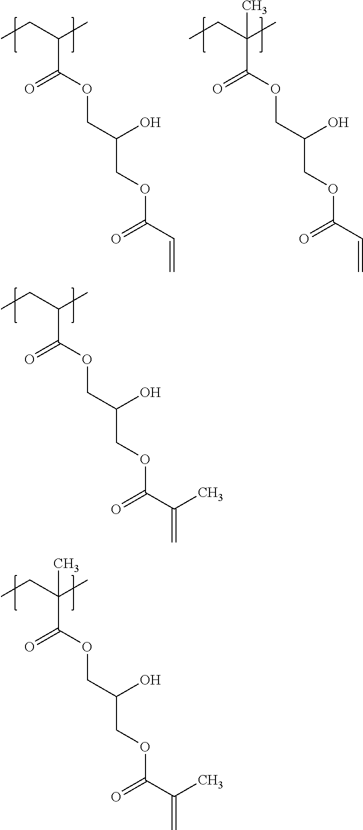

The polymer may have one constitutional unit having a reactive group alone, or two or more kinds thereof.

In a case where the polymer has the constitutional unit having a reactive group, a content of the constitutional unit having a reactive group is preferably 5% by mass to 70% by mass, more preferably 10% by mass to 50% by mass, and still more preferably 20% by mass to 40% by mass with respect to all constitutional units of the polymer.

In addition, the content of the constitutional unit having a reactive group in the polymer is preferably 5 mol % to 70 mol %, more preferably 10 mol % to 60 mol %, and still more preferably 20 mol % to 50 mol % with respect to all constitutional units of the polymer.

Examples of a method for introducing the reactive group into the polymer include a method of reacting a compound such as an epoxy compound, a blocked isocyanate compound, an isocyanate compound, a vinyl sulfone compound, an aldehyde compound, a methylol compound, and a carboxylic acid anhydride with a functional group such as a hydroxy group, a carboxy group, a primary amino group, a secondary amino group, an acetoacetyl group, and a sulfo group. Preferred examples of the method for introducing the reactive group into the polymer include a method in which a polymer having a carboxy group is synthesized by a polymerization reaction, and then a glycidyl (meth)acrylate is reacted with a part of the carboxy group of the obtained polymer by a polymer reaction, thereby introducing a (meth)acryloxy group into the polymer. By this method, a polymer having a (meth)acryloxy group in the side chain can be obtained. The polymerization reaction is preferably carried out under a temperature condition of 70° C. to 100° C., and more preferably carried out under a temperature condition of 80° C. to 90° C. As a polymerization initiator used in the polymerization reaction, an azo-based initiator is preferable, and for example, V-601 (product name) or V-65 (product name) manufactured by FUJIFILM Wako Pure Chemical Corporation is more preferable. The polymer reaction is preferably carried out under a temperature condition of 80° C. to 110° C. In the above-described polymer reaction, it is preferable to use a catalyst such as an ammonium salt.

As the polymer, the following polymers are preferable. Content ratios (a to d) and weight-average molecular weights Mw of each of the constitutional units shown below can be appropriately changed according to the purpose.

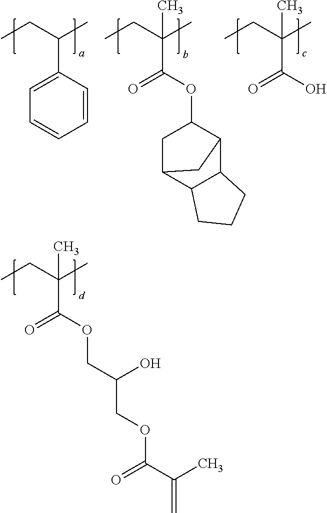

Preferred ranges of the content ratios (a to d) of each constitutional unit are shown below.
a: 20% by mass to 60% by mass
b: 10% by mass to 50% by mass
c: 5.0% by mass to 25% by mass
d: 10% by mass to 50% by mass

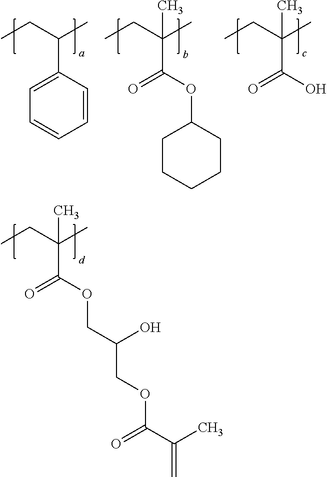

Preferred ranges of the content ratios (a to d) of each constitutional unit are shown below.
a: 20% by mass to 60% by mass
b: 10% by mass to 50% by mass
c: 5.0% by mass to 25% by mass
d: 10% by mass to 50% by mass

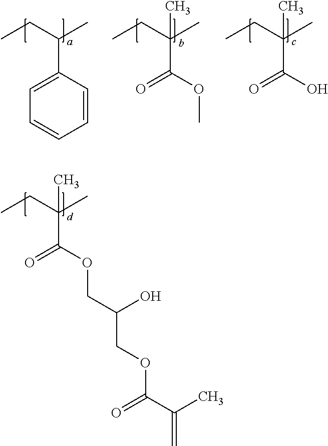

Preferred ranges of the content ratios (a to d) of each constitutional unit are shown below.
a: 30% by mass to 65% by mass
b: 1.0% by mass to 20% by mass
c: 5.0% by mass to 25% by mass
d: 10% by mass to 50% by mass

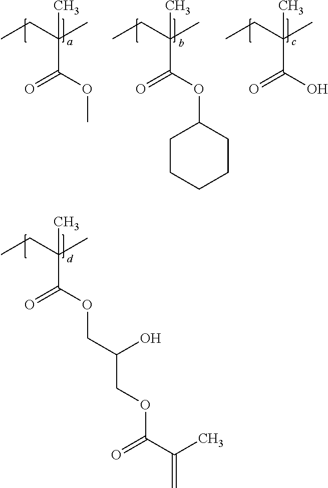

Preferred ranges of the content ratios (a to d) of each constitutional unit are shown below.
a: 1.0% by mass to 20% by mass
b: 20% by mass to 60% by mass
c: 5.0% by mass to 25% by mass
d: 10% by mass to 50% by mass

The polymer may include a polymer (hereinafter, also referred to as a “polymer X”) having a constitutional unit having a carboxylic acid anhydride structure. The carboxylic acid anhydride structure may be either a chain carboxylic acid anhydride structure or a cyclic carboxylic acid anhydride structure, and a cyclic carboxylic acid anhydride structure is preferable. The ring of the cyclic carboxylic acid anhydride structure is preferably a 5- to 7-membered ring, more preferably a 5-membered ring or a 6-membered ring, and still more preferably a 5-membered ring.

The constitutional unit having a carboxylic acid anhydride structure is preferably a constitutional unit containing a divalent group obtained by removing two hydrogen atoms from a compound represented by Formula P-1 in a main chain, or a constitutional unit in which a monovalent group obtained by removing one hydrogen atom from a compound represented by Formula P-1 is bonded to the main chain directly or through a divalent linking group.

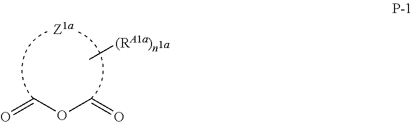

In Formula P-1, R^{Ala} represents a substituent, n^{1a} pieces of R^{Ala}'s may be the same or different, Z^{1a} represents a divalent group forming a ring including —C(═O)—O—C(═O)—, and n^{1a} represents an integer of 0 or more.

Examples of the substituent represented by R^{Ala} include an alkyl group.

Z^{1a} is preferably an alkylene group having 2 to 4 carbon atoms, more preferably an alkylene group having 2 or 3 carbon atoms, and still more preferably an alkylene group having 2 carbon atoms.

n^{1a} represents an integer of 0 or more. In a case where Z^{1a} represents an alkylene group having 2 to 4 carbon atoms, n^{1a} is preferably an integer of 0 to 4, more preferably an integer of 0 to 2, and still more preferably 0.

In a case where n^{1a} represents an integer of 2 or more, a plurality of R^{Ala}'s existing may be the same or different. In addition, the plurality of R^{Ala}'s existing may be bonded to each other to form a ring, but it is preferable that they are not bonded to each other to form a ring.

As the constitutional unit having a carboxylic acid anhydride structure, a constitutional unit derived from an unsaturated carboxylic acid anhydride is preferable, a constitutional unit derived from an unsaturated cyclic carboxylic acid anhydride is more preferable, a constitutional unit derived from an unsaturated aliphatic carboxylic acid anhydride is still more preferable, a constitutional unit derived from maleic acid anhydride or itaconic anhydride is particularly preferable, and a constitutional unit derived from maleic acid anhydride is most preferable.

Hereinafter, specific examples of the constitutional unit having a carboxylic acid anhydride structure will be described, but the constitutional unit having a carboxylic acid anhydride structure is not limited to these specific examples. In the following constitutional units, Rx represents a hydrogen atom, a methyl group, a CH₂OH group, or a CF₃ group, and Me represents a methyl group.

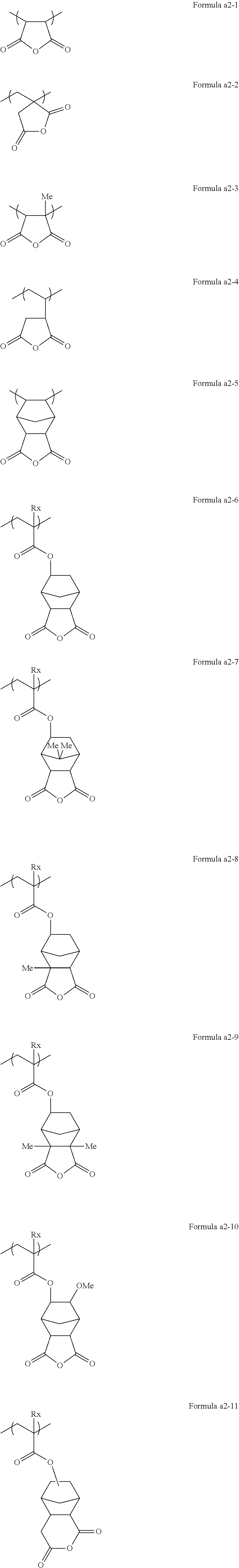

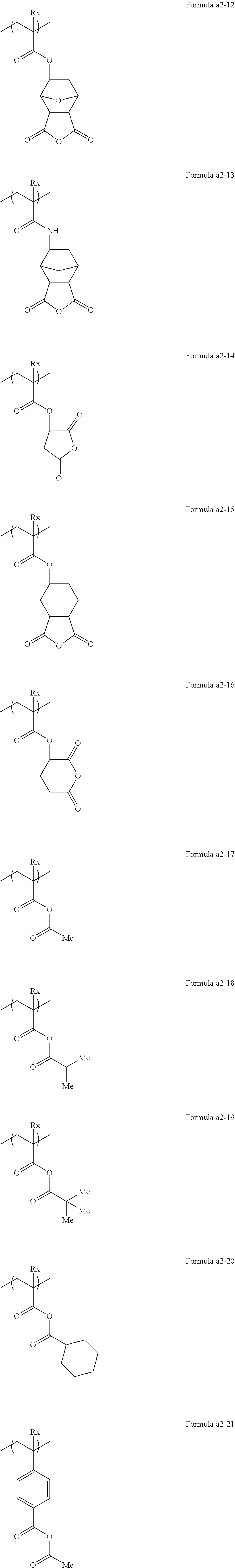

The polymer X may have one constitutional unit having a carboxylic acid anhydride structure alone, or two or more kinds thereof.

The total content of the constitutional unit having a carboxylic acid anhydride structure is preferably 0 mol % to 60 mol %, more preferably 5 mol % to 40 mol %, and still more preferably 10 mol % to 35 mol % with respect to all constitutional units of the polymer X.

The photosensitive layer may contain only one kind of the polymer X, or may contain two or more kinds thereof.

In a case where the photosensitive layer contains the polymer X, a content of the polymer X is preferably 0.1% by mass to 30% by mass, more preferably 0.2% by mass to 20% by mass, still more preferably 0.5% by mass to 20% by mass, and particularly preferably 1% by mass to 20% by mass with respect to the total mass of the photosensitive layer.

A weight-average molecular weight (Mw) of the polymer is preferably 5,000 or more, more preferably 10,000 or more, still more preferably 10,000 to 50,000, and particularly preferably 20,000 to 30,000.

An acid value of the polymer is preferably 10 mgKOH/g to 200 mgKOH/g, more preferably 60 mgKOH/g to 200 mgKOH/g, still more preferably 60 mgKOH/g to 150 mgKOH/g, and particularly preferably 70 mgKOH/g to 125 mgKOH/g. The acid value of the polymer is a value measured according to the method described in “JIS K 0070: 1992”.

From the viewpoint of developability, a dispersity of the polymer is preferably 1.0 to 6.0, more preferably 1.0 to 5.0, still more preferably 1.0 to 4.0, and particularly preferably 1.0 to 3.0.

The photosensitive layer may contain only one kind of the polymer, or may contain two or more kinds thereof.

A content of the polymer is preferably 10% by mass to 90% by mass, more preferably 20% by mass to 80% by mass, and still more preferably 30% by mass to 70% by mass with respect to the total mass of the photosensitive layer.

The photosensitive layer preferably contains a polymerizable compound. Hereinafter, the polymerizable compound will be described.

The polymerizable compound is a compound having a polymerizable group. Examples of the polymerizable group include a radically polymerizable group and a cationically polymerizable group, and a radically polymerizable group is preferable.

The polymerizable compound preferably includes a radically polymerizable compound having an ethylenically unsaturated group (hereinafter, also simply referred to as an “ethylenically unsaturated compound”). As the ethylenically unsaturated group, a (meth)acryloxy group is preferable. The ethylenically unsaturated compound in the present specification is a compound other than the above-described polymer, and preferably has a molecular weight of less than 5,000.

Examples of one suitable aspect of the polymerizable compound include a compound represented by Formula (M) (simply referred to as a “compound M”).

Q²-R¹-Q¹: Formula (M)

In Formula (M), Q¹ and Q² each independently represent a (meth)acryloyloxy group, and R¹ represents a divalent linking group having a chain structure.

From the viewpoint of easiness of synthesis, Q¹ and Q² in Formula (M) preferably have the same group. From the viewpoint of reactivity, Q¹ and Q² in Formula (M) are preferably acryloyloxy groups.

R¹ in Formula (M) is preferably an alkylene group, an alkyleneoxyalkylene group (-L¹-O-L¹-), or a polyalkyleneoxyalkylene group (-(L¹-O)ₚ-L¹-), more preferably a hydrocarbon group having 2 to 20 carbon atoms or a polyalkyleneoxyalkylene group, still more preferably an alkylene group having 4 to 20 carbon atoms, and particularly preferably a linear alkylene group having 6 to 18 carbon atoms. It is sufficient that the hydrocarbon group has a chain structure at least in part, and a portion other than the chain structure is not particularly limited. For example, the portion may be a branched chain, a cyclic or a linear alkylene group having 1 to 5 carbon atoms, an arylene group, an ether bond, or a combination thereof, and an alkylene group or a group in which two or more alkylene groups and one or more arylene groups are combined is preferable, an alkylene group is more preferable, and a linear alkylene group is still more preferable. L's each independently represent an alkylene group, and an ethylene group, a propylene group, or a butylene group is preferable and an ethylene group or a 1,2-propylene group is more preferable. p represents an integer of 2 or more, and is preferably an integer of 2 to 10.

The number of atoms in the shortest linking chain which links Q¹ and Q² in the compound M is preferably 3 to 50, more preferably 4 to 40, still more preferably 6 to 20, and particularly preferably 8 to 12. In the present disclosure, the “number of atoms in the shortest linking chain which links Q¹ and Q²” is the shortest number of atoms linking from an atom in R¹ linked to Q¹ to an atom in R¹ linked to Q².

Specific examples of the compound M include 1,3-butanediol di(meth)acrylate, tetramethylene glycol di(meth)acrylate, neopentyl glycol di(meth)acrylate, 1,6-hexanediol di(meth)acrylate, 1,7-heptanediol di(meth)acrylate, 1,8-octanediol di(meth)acrylate, 1,9-nonanediol di(meth)acrylate, 1,10-decanediol di(meth)acrylate, hydrogenated bisphenol A di(meth)acrylate, hydrogenated bisphenol F di(meth)acrylate, polyethylene glycol di(meth)acrylate, polypropylene glycol di(meth)acrylate, poly (ethylene glycol/propylene glycol) di(meth)acrylate, and polybutylene glycol di(meth)acrylate. The above-described ester monomers can also be used as a mixture. Among the above-described compounds, at least one compound selected from the group consisting of 1,6-hexanediol di(meth)acrylate, 1,9-nonanediol di(meth)acrylate, 1,10-decanediol di(meth)acrylate, and neopentyl glycol di(meth)acrylate is preferable, at least one compound selected from the group consisting of 1,6-hexanediol di(meth)acrylate, 1,9-nonanediol di(meth)acrylate, and 1,10-decanediol di(meth)acrylate is more preferable, and at least one compound selected from the group consisting of 1,9-nonanediol di(meth)acrylate and 1,10-decanediol di(meth)acrylate is still more preferable.

Examples of one suitable aspect of the polymerizable compound include a bi- or higher functional ethylenically unsaturated compound. In the present disclosure, the “bi- or higher functional ethylenically unsaturated compound” means a compound having two or more ethylenically unsaturated groups in one molecule. As the ethylenically unsaturated group in the ethylenically unsaturated compound, a (meth)acryloyl group is preferable. As the ethylenically unsaturated compound, a (meth)acrylate compound is preferable.

The bifunctional ethylenically unsaturated compound is not particularly limited and can be appropriately selected from a known compound. Examples of the bifunctional ethylenically unsaturated compound other than the above-described compound M include tricyclodecane dimethanol di(meth)acrylate and 1,4-cyclohexanediol di(meth)acrylate.

Examples of a commercially available product of the bifunctional ethylenically unsaturated compound include tricyclodecane dimethanol diacrylate (product name: NK ESTER A-DCP, manufactured by Shin-Nakamura Chemical Co., Ltd.), tricyclodecane dimethanol dimethacrylate (product name: NK ESTER DCP, manufactured by Shin-Nakamura Chemical Co., Ltd.), 1,9-nonanediol diacrylate (product name: NK ESTER A-NOD-N, manufactured by Shin-Nakamura Chemical Co., Ltd.), and 1,6-hexanediol diacrylate (product name: NK ESTER A-HD-N, manufactured by Shin-Nakamura Chemical Co., Ltd.).

The tri- or higher functional ethylenically unsaturated compound is not particularly limited and can be appropriately selected from a known compound. Examples of the tri- or higher functional ethylenically unsaturated compound include dipentaerythritol (tri/tetra/penta/hexa) (meth)acrylate, pentaerythritol (tri/tetra) (meth)acrylate, trimethylolpropane tri(meth)acrylate, ditrimethylolpropane tetra(meth)acrylate, isocyanuric acid (meth)acrylate, and a (meth)acrylate compound of a glycerin tri(meth)acrylate skeleton. Here, the “(tri/tetra/penta/hexa) (meth)acrylate” has a concept including tri(meth)acrylate, tetra(meth)acrylate, penta(meth)acrylate, and hexa(meth)acrylate, and the “(tri/tetra) (meth)acrylate” has a concept including tri(meth)acrylate and tetra(meth)acrylate.

Examples of the polymerizable compound also include a caprolactone-modified compound of a (meth)acrylate compound (KAYARAD (registered trademark) DPCA-20 manufactured by Nippon Kayaku Co., Ltd., A-9300-1CL manufactured by Shin-Nakamura Chemical Co., Ltd., or the like), an alkylene oxide-modified compound of a (meth)acrylate compound (KAYARAD (registered trademark) RP-1040 manufactured by Nippon Kayaku Co., Ltd., ATM-35E or A-9300 manufactured by Shin-Nakamura Chemical Co., Ltd., EBECRYL (registered trademark) 135 manufactured by Daicel-Allnex Ltd., or the like), and ethoxylated glycerin triacrylate (NK ESTER A-GLY-9E manufactured by Shin-Nakamura Chemical Co., Ltd., or the like).

Examples of the polymerizable compound also include a urethane (meth)acrylate compound. Examples of the urethane (meth)acrylate include urethane di(meth)acrylate, and examples thereof include propylene oxide-modified urethane di(meth)acrylate and ethylene oxide and propylene oxide-modified urethane di(meth)acrylate. In addition, examples of the urethane (meth)acrylate also include tri- or higher functional urethane (meth)acrylate. The lower limit of the number of functional groups is more preferably 6 or more and still more preferably 8 or more. The upper limit of the number of functional groups is preferably 20 or less. Examples of the tri- or higher functional urethane (meth)acrylate include 8UX-015A (manufactured by Taisei Fine Chemical Co., Ltd.), UA-32P (manufactured by Shin-Nakamura Chemical Co., Ltd.), U-15HA (manufactured by Shin-Nakamura Chemical Co., Ltd.), UA-1100H (manufactured by Shin-Nakamura Chemical Co., Ltd.), AH-600 (product name) manufactured by KYOEISHA CHEMICAL Co., LTD, UA-306H, UA-306T, UA-306I, UA-510H, and UX-5000 (all manufactured by Nippon Kayaku Co., Ltd.).

Examples of one suitable aspect of the polymerizable compound include an ethylenically unsaturated compound having an acid group. Examples of the acid group include a phosphoric acid group, a sulfo group, and a carboxy group. Among these, as the acid group, a carboxy group is preferable. Examples of the ethylenically unsaturated compound having an acid group include a tri- or tetra-functional ethylenically unsaturated compound having an acid group [component obtained by introducing a carboxy group to pentaerythritol tri- and tetra-acrylate (PETA) skeleton (acid value: 80 to 120 mgKOH/g)), and a penta- to hexa-functional ethylenically unsaturated compound having an acid group [component obtained by introducing a carboxy group to dipentaerythritol penta- and hexa-acrylate (DPHA) skeleton (acid value: 25 to 70 mgKOH/g)]. The tri- or higher functional ethylenically unsaturated compound having an acid group may be used in combination with the bifunctional ethylenically unsaturated compound having an acid group, as necessary.

As the ethylenically unsaturated compound having an acid group, at least one selected from the group consisting of bi- or higher functional ethylenically unsaturated compound having a carboxy group and a carboxylic acid anhydride thereof is preferable. In a case where the ethylenically unsaturated compound having an acid group is at least one selected from the group consisting of bi- or higher functional ethylenically unsaturated compound having a carboxy group and a carboxylic acid anhydride thereof, developability and film hardness are further enhanced. The bi- or higher functional ethylenically unsaturated compound having a carboxy group is not particularly limited and can be appropriately selected from a known compound. Examples of the bi- or higher functional ethylenically unsaturated compound having a carboxy group include ARONIX (registered trademark) TO-2349 manufactured by Toagosei Co., Ltd., ARONIX (registered trademark) M-520 manufactured by Toagosei Co., Ltd., and ARONIX (registered trademark) M-510 manufactured by Toagosei Co., Ltd.

As the ethylenically unsaturated compound having an acid group, polymerizable compounds having an acid group, which are described in paragraphs [0025] to [0030] of JP2004-239942A, are preferable, and the contents described in this publication are incorporated in the present specification.

Examples of the polymerizable compound also include a compound obtained by reacting a polyhydric alcohol with an α,β-unsaturated carboxylic acid, a compound obtained by reacting a glycidyl group-containing compound with an α,β-unsaturated carboxylic acid, urethane monomer such as a (meth)acrylate compound having a urethane bond, phthalate compounds such as γ-chloro-β-hydroxypropyl-β′-(meth)acryloyloxyethyl-o-phthalate, β-hydroxyethyl-β′-(meth)acryloyloxyethyl-o-phthalate, and β-hydroxypropyl-β′-(meth)acryloyloxyethyl-o-phthalate, and (meth)acrylic acid alkyl esters. These compounds may be used alone or in combination of two or more kinds thereof.

Examples of the compound obtained by reacting a polyhydric alcohol with an α,β-unsaturated carboxylic acid include bisphenol A-based (meth)acrylate compounds such as 2,2-bis(4-((meth)acryloxypolyethoxy)phenyl)propane, 2,2-bis(4-((meth)acryloxypolypropoxy)phenyl)propane, and 2,2-bis(4-((meth)acryloxypolyethoxypolypropoxy)phenyl)propane, polyethylene glycol di(meth)acrylate having 2 to 14 ethylene oxide groups, polypropylene glycol di(meth)acrylate having 2 to 14 propylene oxide groups, polyethylene polypropylene glycol di(meth)acrylate having 2 to 14 ethylene oxide groups and 2 to 14 propylene oxide groups, trimethylolpropane di(meth)acrylate, trimethylolpropane tri(meth)acrylate, trimethylolpropane ethoxy tri(meth)acrylate, trimethylolpropane diethoxy tri(meth)acrylate, trimethylolpropane triethoxy tri(meth)acrylate, trimethylolpropane tetraethoxy tri(meth)acrylate, trimethylolpropane pentaethoxy tri(meth)acrylate, di(trimethylolpropane) tetraacrylate, tetramethylolmethane tri(meth)acrylate, tetramethylolmethane tetra(meth)acrylate, dipentaerythritol tetra(meth)acrylate, dipentaerythritol penta(meth)acrylate, and dipentaerythritol hexa(meth)acrylate. Among these, an ethylenically unsaturated compound having a tetramethylolmethane structure or a trimethylolpropane structure is preferable, and tetramethylolmethane tri(meth)acrylate, tetramethylolmethane tetra(meth)acrylate, trimethylolpropane tri(meth)acrylate, or di(trimethylolpropane) tetraacrylate is more preferable.

Among these, as the polymerizable compound (particularly, the ethylenically unsaturated compound), from the viewpoint of excellent developability of the photosensitive layer after transfer, an ethylenically unsaturated compound including an ester bond is also preferable. The ethylenically unsaturated compound including an ester bond is not particularly limited as long as it includes an ester bond in the molecule, but an ethylenically unsaturated compound having a tetramethylolmethane structure or a trimethylolpropane structure is preferable, and tetramethylolmethane tri(meth)acrylate, tetramethylolmethane tetra(meth)acrylate, trimethylolpropane tri(meth)acrylate, or di(trimethylolpropane) tetraacrylate is more preferable.

As the ethylenically unsaturated compound, from the viewpoint of imparting reliability, it is preferable to include an ethylenically unsaturated compound having an aliphatic group having 6 to 20 carbon atoms and the above-described ethylenically unsaturated compound having a tetramethylolmethane structure or a trimethylolpropane structure. Examples of the ethylenically unsaturated compound having an aliphatic structure having 6 or more carbon atoms include 1,9-nonanediol di(meth)acrylate, 1,10-decanediol di(meth)acrylate, and tricyclodecane dimethanol di(meth)acrylate.

Examples of one suitable aspect of the polymerizable compound include a polymerizable compound (preferably, a bifunctional ethylenically unsaturated compound) having an aliphatic hydrocarbon ring structure. As the above-described polymerizable compound, a polymerizable compound having a ring structure in which two or more aliphatic hydrocarbon rings are fused (preferably, a structure selected from the group consisting of a tricyclodecane structure and a tricyclodecene structure) is preferable, a bifunctional ethylenically unsaturated compound having a ring structure in which two or more aliphatic hydrocarbon rings are fused is more preferable, and tricyclodecane dimethanol di(meth)acrylate is still more preferable. As the above-described aliphatic hydrocarbon ring structure, a cyclopentane structure, a cyclohexane structure, a tricyclodecane structure, a tricyclodecene structure, a norbornane structure, or an isophorone structure is preferable.

A molecular weight of the polymerizable compound is preferably 200 to 3,000, more preferably 250 to 2,600, still more preferably 280 to 2,200, and particularly preferably 300 to 2,200.

A proportion of the content of the polymerizable compound having a molecular weight of 300 or less in the polymerizable compounds contained in the photosensitive layer is preferably 30% by mass or less, more preferably 25% by mass or less, and still more preferably 20% by mass or less with respect to the content of all the polymerizable compounds contained in the photosensitive layer.

As one suitable aspect of the photosensitive layer, the photosensitive layer preferably contains the bi- or higher functional ethylenically unsaturated compound, more preferably contains the tri- or higher functional ethylenically unsaturated compound, and still more preferably contains a tri- or tetrafunctional ethylenically unsaturated compound.

In addition, as one suitable aspect of the photosensitive layer, the photosensitive layer preferably contains the bifunctional ethylenically unsaturated compound having an aliphatic hydrocarbon ring structure and the polymer having the constitutional unit having an aliphatic hydrocarbon ring.

In addition, as one suitable aspect of the photosensitive layer, the photosensitive layer preferably contains the compound represented by Formula (M) and the ethylenically unsaturated compound having an acid group, more preferably contains 1,9-nonanediol diacrylate, tricyclodecane dimethanol diacrylate, and a polyfunctional ethylenically unsaturated compound having a carboxylic acid group, and still more preferably contains 1,9-nonanediol diacrylate, tricyclodecane dimethanol diacrylate, and a succinic acid-modified form of dipentaerythritol pentaacrylate.

In addition, as one suitable aspect of the photosensitive layer, the photosensitive layer preferably contains the compound represented by Formula (M), the ethylenically unsaturated compound having an acid group, and a thermal crosslinking compound described later, and more preferably contains the compound represented by Formula (M), the ethylenically unsaturated compound having an acid group, and a blocked isocyanate compound described later.

In addition, as one suitable aspect of the photosensitive layer, from the viewpoint of development residue inhibitory property and rust preventive property, the photosensitive layer preferably contains the bifunctional ethylenically unsaturated compound (preferably, a bifunctional (meth)acrylate compound) and the tri- or higher functional ethylenically unsaturated compound (preferably, a tri- or higher functional (meth)acrylate compound).

A mass ratio of a content of the bifunctional ethylenically unsaturated compound and a content of the tri- or higher functional ethylenically unsaturated compound is preferably 10:90 to 90:10 and more preferably 30:70 to 70:30.

The content of the bifunctional ethylenically unsaturated compound is preferably 20% by mass to 80% by mass and more preferably 30% by mass to 70% by mass with respect to the total amount of all ethylenically unsaturated compounds.

A content of the bifunctional ethylenically unsaturated compound in the photosensitive layer is preferably 10% by mass to 60% by mass and more preferably 15% by mass to 40% by mass.

As one suitable aspect of the photosensitive layer, from the viewpoint of rust preventive property, the photosensitive layer preferably contains the compound M and the bifunctional ethylenically unsaturated compound having an aliphatic hydrocarbon ring structure.

As one suitable aspect of the photosensitive layer, from the viewpoint of substrate adhesiveness, development residue inhibitory property, and rust preventive property, the photosensitive layer preferably contains the compound M and the ethylenically unsaturated compound having an acid group, more preferably contains the compound M, the bifunctional ethylenically unsaturated compound having an aliphatic hydrocarbon ring structure, and the ethylenically unsaturated compound having an acid group, still more preferably contains the compound M, the bifunctional ethylenically unsaturated compound having an aliphatic hydrocarbon ring structure, the tri- or higher functional ethylenically unsaturated compound, and the ethylenically unsaturated compound having an acid group, and particularly preferably contains the compound M, the bifunctional ethylenically unsaturated compound having an aliphatic hydrocarbon ring structure, the tri- or higher functional ethylenically unsaturated compound, the ethylenically unsaturated compound having an acid group, and the urethane (meth)acrylate compound.

As one suitable aspect of the photosensitive layer, from the viewpoint of substrate adhesiveness, development residue inhibitory property, and rust preventive property, the photosensitive layer preferably contains 1,9-nonanediol diacrylate and the polyfunctional ethylenically unsaturated compound having a carboxylic acid group, more preferably contains 1,9-nonanediol diacrylate, tricyclodecane dimethanol diacrylate, and the polyfunctional ethylenically unsaturated compound having a carboxylic acid group, still more preferably contains 1,9-nonanediol diacrylate, tricyclodecane dimethanol diacrylate, dipentaerythritol hexaacrylate, and an ethylenically unsaturated compound having a carboxylic acid group, and particularly preferably contains 1,9-nonanediol diacrylate, tricyclodecane dimethanol diacrylate, an ethylenically unsaturated compound having a carboxylic acid group, and a urethane acrylate compound.

The photosensitive layer may contain a monofunctional ethylenically unsaturated compound as the ethylenically unsaturated compound. A content of the bi- or higher functional ethylenically unsaturated compound in the ethylenically unsaturated compound is preferably 60% by mass to 100% by mass, more preferably 80% by mass to 100% by mass, and still more preferably 90% by mass to 100% by mass with respect to the total content of all ethylenically unsaturated compounds contained in the photosensitive layer.

The polymerizable compound preferably has a bisphenol structure from the viewpoint of improving the resolution by suppressing the swelling of the photosensitive layer due to the developer. Examples of the bisphenol structure include a bisphenol A structure derived from bisphenol A (2,2-bis(4-hydroxyphenyl)propane), a bisphenol F structure derived from bisphenol F (2,2-bis(4-hydroxyphenyl)methane), and a bisphenol B structure derived from bisphenol B (2,2-bis(4-hydroxyphenyl)butane), and a bisphenol A structure is preferable.

Examples of the polymerizable compound having a bisphenol structure include a compound having a bisphenol structure and two polymerizable groups (preferably (meth)acryloyl groups) bonded to both ends of the bisphenol structure. The two polymerizable groups bonded to both ends of the bisphenol structure may be directly bonded or may be bonded through one or more alkyleneoxy groups. As the alkyleneoxy group added to both ends of the bisphenol structure, an ethyleneoxy group or a propyleneoxy group is preferable, and an ethyleneoxy group is more preferable. The number of alkyleneoxy groups added to the bisphenol structure is not particularly limited, but is preferably 4 to 16 and more preferably 6 to 14 per one molecule. The polymerizable compound having a bisphenol structure is described in paragraphs [0072] to [0080] of JP2016-224162A, and the content described in this publication is incorporated in the present specification.

The polymerizable compound having a bisphenol structure is preferably a bifunctional ethylenically unsaturated compound having a bisphenol A structure, and it is more preferably 2,2-bis(4-((meth)acryloxypolyalkoxy)phenyl)propane. Examples of 2,2-bis(4-((meth)acryloxypolyalkoxy)phenyl)propane include 2,2-bis(4-(methacryloxydiethoxy)phenyl)propane (FA-324M, manufactured by Showa Denko Materials co., Ltd.), 2,2-bis(4-(methacryloxyethoxypropoxy)phenyl)propane, 2,2-bis(4-(methacryloxypentethoxy)phenyl)propane (BPE-500, manufactured by Shin-Nakamura Chemical Co., Ltd.), 2,2-bis(4-(methacryloxydodecaethoxytetrapropoxy)phenyl)propane (FA-3200MY, manufactured by Showa Denko Materials co., Ltd.), 2,2-bis(4-(methacryloxypentadecaethoxy)phenyl)propane (BPE-1300, manufactured by Shin-Nakamura Chemical Co., Ltd.), 2,2-bis(4-(methacryloxydiethoxy)phenyl)propane (BPE-200, manufactured by Shin-Nakamura Chemical Co., Ltd.), and ethoxylated (10) bisphenol A diacrylate (NK ESTER A-BPE-10, manufactured by Shin-Nakamura Chemical Co., Ltd.).

The polymerizable compound is preferably a compound represented by General Formula (B1).

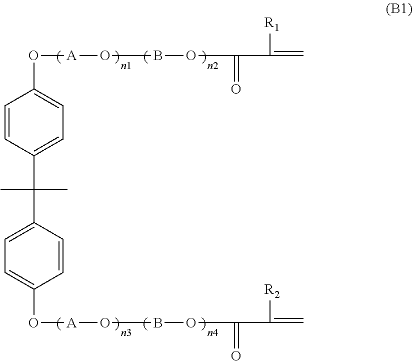

In General Formula B1, R₁, and R₂ each independently represent a hydrogen atom or a methyl group. A represents C₂H₄. B represents C₃H₆. n1 and n3 are each independently an integer of 1 to 39, and n1+n3 is an integer of 2 to 40. n2 and n4 are each independently an integer of 0 to 29, and n2+n4 is an integer of 0 to 30. The sequences of constitutional units of -(A-O)— and —(B—O)— may be a random type or a block type. In a case of a block, either -(A-O)— or —(B—O)— may be on the bisphenyl group side.

In one aspect, n1+n2+n3+n4 is preferably 2 to 20, more preferably 2 to 16, and still more preferably 4 to 12. In addition, n2+n4 is preferably 0 to 10, more preferably 0 to 4, still more preferably 0 to 2, and particularly preferably 0.

The polymerizable compound (particularly, the ethylenically unsaturated compound) may be used alone or in combination of two or more kinds thereof.

A content of the polymerizable compound (particularly, the ethylenically unsaturated compound) in the photosensitive layer is preferably 1% by mass to 70% by mass, more preferably 5% by mass to 70% by mass, still more preferably 5% by mass to 60% by mass, and particularly preferably 5% by mass to 50% by mass with respect to the total mass of the photosensitive layer.

It is preferable that the photosensitive layer contains a polymerization initiator. Hereinafter, the polymerization initiator will be described.

As the polymerization initiator, a photopolymerization initiator is preferable. The photopolymerization initiator is not particularly limited and a known photopolymerization initiator can be used. Examples of the photopolymerization initiator include a photopolymerization initiator having an oxime ester structure (hereinafter, also referred to as an “oxime-based photopolymerization initiator”), a photopolymerization initiator having an α-aminoalkylphenone structure (hereinafter, also referred to as an “α-aminoalkylphenone-based photopolymerization initiator”), a photopolymerization initiator having an α-hydroxyalkylphenone structure (hereinafter also referred to as an “α-hydroxyalkylphenone-based photopolymerization initiator”), a photopolymerization initiator having an acylphosphine oxide structure, (hereinafter, also referred to as an “acylphosphine oxide-based photopolymerization initiator”), and a photopolymerization initiator having an N-phenylglycine structure (hereinafter, also referred to as an “N-phenylglycine-based photopolymerization initiator”).

The photopolymerization initiator preferably includes at least one kind selected from the group consisting of the oxime-based photopolymerization initiator, the α-aminoalkylphenone-based photopolymerization initiator, the α-hydroxyalkylphenone-based photopolymerization initiator, the biimidazole-based polymerization initiator, and the N-phenylglycine-based photopolymerization initiator, and more preferably includes at least one kind selected from the group consisting of the oxime-based photopolymerization initiator, the α-aminoalkylphenone-based photopolymerization initiator, and the N-phenylglycine-based photopolymerization initiator.

In addition, as the photopolymerization initiator, for example, polymerization initiators described in paragraphs [0031] to [0042] of JP2011-95716A and paragraphs [0064] to [0081] of JP2015-014783A may be used.

Examples of a commercially available product of the photopolymerization initiator include 1-[4-(phenylthio)phenyl]-1,2-octanedione-2-(O-benzoyloxime) [product name: IRGACURE (registered trademark) OXE-01, manufactured by BASF SE], 1-[9-ethyl-6-(2-methylbenzoyl)-9H-carbazol-3-yl]ethanone-1-(0-acetyloxime) [product name: IRGACURE (registered trademark) OXE-02, manufactured by BASF SE], IRGACURE (registered trademark) OXE-03 (manufactured by BASF SE), IRGACURE (registered trademark) OXE-04 (manufactured by BASF SE), 2-(dimethylamino)-2-[(4-methylphenyl)methyl]-1-[4-(4-morpholinyl)phenyl]-1-butanone [product name: Omnirad (registered trademark) 379EG, manufactured by IGM Resins B.V.], 2-methyl-1-(4-methylthiophenyl)-2-morpholinopropan-1-one [product name: Omnirad (registered trademark) 907, manufactured by IGM Resins B.V.], 2-hydroxy-1-{4-[4-(2-hydroxy-2-methylpropionyl)benzyl]phenyl}-2-methylpropan-1-one [product name: Omnirad (registered trademark) 127, manufactured by IGM Resins B.V], 2-benzyl-2-dimethylamino-1-(4-morpholinophenyl)butanone-1 [product name: Omnirad (registered trademark) 369, manufactured by IGM Resins B.V], 2-hydroxy-2-methyl-1-phenylpropan-1-one [product name: Omnirad (registered trademark) 1173, manufactured by IGM Resins B.V.], 1-hydroxy cyclohexyl phenyl ketone [product name: Omnirad (registered trademark) 184, manufactured by IGM Resins B.V.], 2,2-dimethoxy-1,2-diphenylethan-1-one (product name: Omnirad (registered trademark) 651, manufactured by IGM Resins B.V.], an oxime ester-based photopolymerization initiator [product name: Lunar (registered trademark) 6, manufactured by DKSH Management Ltd.], 1-[4-(phenylthio)phenyl]-3-cyclopentylpropan-1,2-dione-2-(O-benzoyloxime) (product name: TR-PBG-305, manufactured by TRONLY), 1,2-propanedione, 3-cyclohexyl-1-[9-ethyl-6-(2-furanylcarbonyl)-9H-carbazole-3-yl]-, 2-(0-acetyloxime) (product name: TR-PBG-326, manufactured by TRONLY), 3-cyclohexyl-1-(6-(2-(benzoyloxyimino)hexanoyl)-9-ethyl-9H-carbazole-3-yl)-propan-1,2-dione-2-(O-benzoyloxime) (product name: TR-PBG-391, manufactured by TRONLY), and APi-307 (1-(biphenyl-4-yl)-2-methyl-2-morpholinopropan-1-one, manufactured by Shenzhen UV-ChemTech Co., Ltd.).

The photoradical polymerization initiator which is one kind of the photopolymerization initiator preferably includes at least one selected from the group consisting of a 2,4,5-triarylimidazole dimer and a derivative thereof. Two 2,4,5-triarylimidazole structures in the 2,4,5-triarylimidazole dimer and a derivative thereof may be the same or different from each other. Examples of the derivative of the 2,4,5-triarylimidazole dimer include a 2-(o-chlorophenyl)-4,5-diphenylimidazole dimer, a 2-(o-chlorophenyl)-4,5-di(methoxyphenyl)imidazole dimer, a 2-(o-fluorophenyl)-4,5-diphenylimidazole dimer, a 2-(o-methoxyphenyl)-4,5-diphenylimidazole dimer, and a 2-(p-methoxyphenyl)-4,5-diphenylimidazole dimer.

The polymerization initiator may be used alone or in combination of two or more kinds thereof. In a case of using two or more kinds thereof, it is preferable to use at least one selected from the oxime-based photopolymerization initiator, the α-aminoalkylphenone-based polymerization initiator, or the α-hydroxyalkylphenone-based photopolymerization initiator.

In a case where the photosensitive layer contains the polymerization initiator, a content of the polymerization initiator is preferably 0.1% by mass or more, more preferably 0.5% by mass or more, and still more preferably 1.0% by mass or more with respect to the total mass of the photosensitive layer. In addition, the upper limit thereof is preferably 10% by mass or less and more preferably 5% by mass or less with respect to the total mass of the photosensitive layer.

The photosensitive layer may contain a heterocyclic compound. Hereinafter, the heterocyclic compound will be described.

A heterocyclic ring included in the heterocyclic compound may be either a monocyclic or polycyclic heterocyclic ring. Examples of a heteroatom included in the heterocyclic compound include an oxygen atom, a nitrogen atom, and a sulfur atom. The heterocyclic compound preferably has at least one atom selected from the group consisting of a nitrogen atom, an oxygen atom, and a sulfur atom, and more preferably has a nitrogen atom.

Examples of the heterocyclic compound include a triazole compound, a benzotriazole compound, a tetrazole compound, a thiadiazole compound, a triazine compound, a rhodanine compound, a thiazole compound, a benzothiazole compound, a benzimidazole compound, a benzoxazole compound, and a pyrimidine compound. Among the above-described compounds, the heterocyclic compound is preferably at least one compound selected from the group consisting of a triazole compound, a benzotriazole compound, a tetrazole compound, a thiadiazole compound, a triazine compound, a rhodanine compound, a thiazole compound, a benzimidazole compounds, and a benzoxazole compound, and more preferably at least one compound selected from the group consisting of a triazole compound, a benzotriazole compound, a tetrazole compound, a thiadiazole compound, a thiazole compound, a benzothiazole compound, a benzimidazole compound, and a benzoxazole compound.

Preferred specific examples of the heterocyclic compound are shown below. Examples of the triazole compound and the benzotriazole compound include the following compounds.

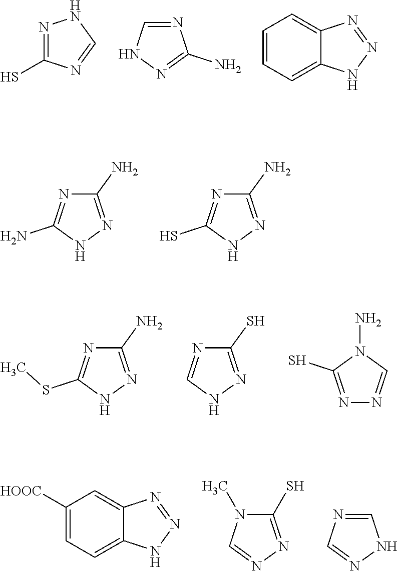

Examples of the tetrazole compound include the following compounds.

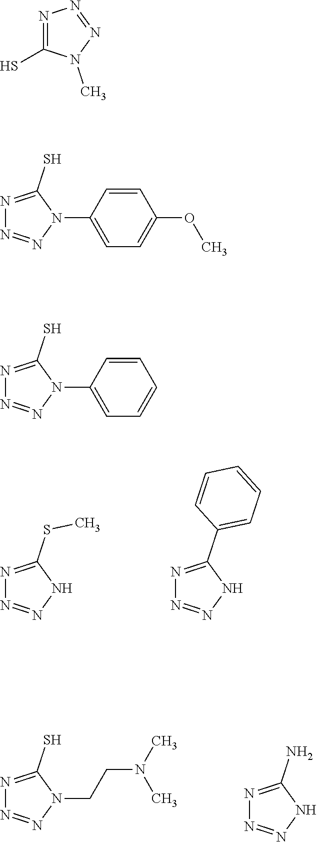

Examples of the thiadiazole compound include the following compounds.

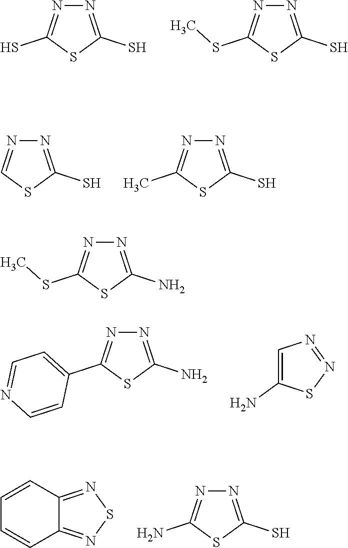

Examples of the triazine compound include the following compounds.

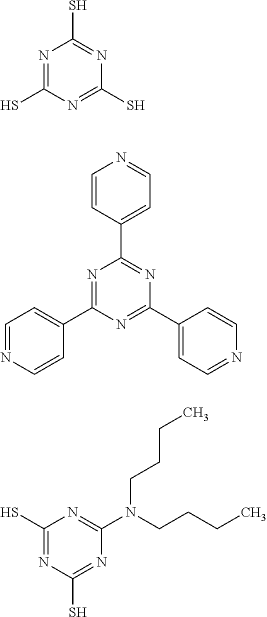

Examples of the rhodanine compound include the following compounds.

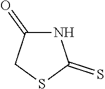

Examples of the thiazole compound include the following compounds.

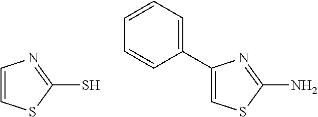 [SMILES: Sc1nccs1 ; Nc1nc(-c2ccccc2)cs1]

Examples of the benzothiazole compound include the following compounds.

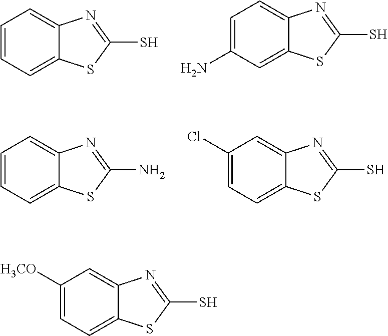 [SMILES: Sc1nc2ccccc2s1 ; Nc1ccc2nc(S)sc2c1 ; Nc1nc2ccccc2s1 ; Sc1nc2cc(Cl)ccc2s1 ; COc1ccc2sc(S)nc2c1]

Examples of the benzimidazole compound include the following compounds.

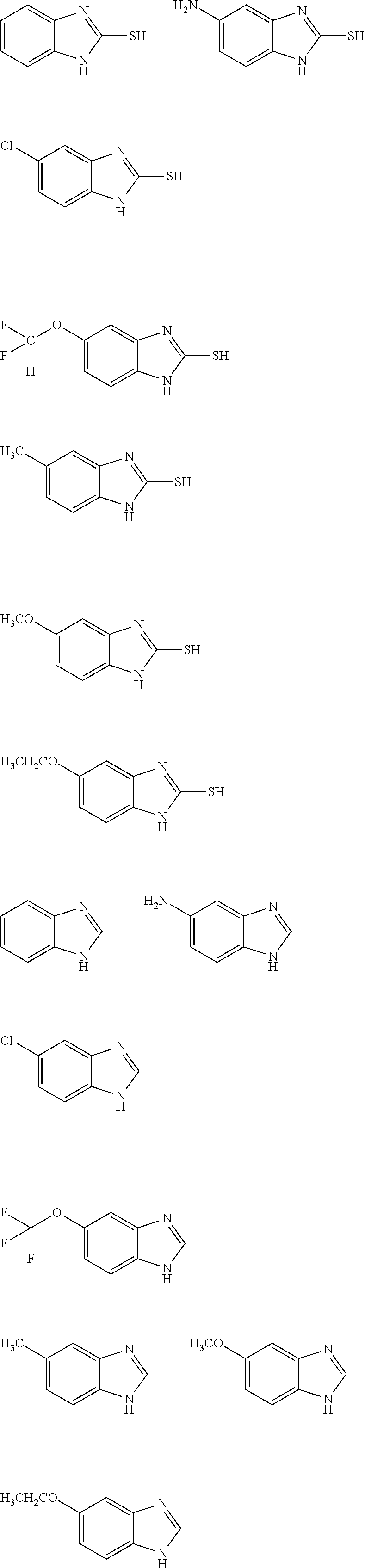

Examples of the benzoxazole compound include the following compounds.

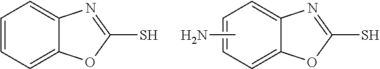

The heterocyclic compound may be used alone or in combination of two or more kinds thereof.

In a case where the photosensitive layer contains the heterocyclic compound, a content of the heterocyclic compound is preferably 0.01% by mass to 20.0% by mass, more preferably 0.10% by mass to 10.0% by mass, still more preferably 0.30% by mass to 8.0% by mass, and particularly preferably 0.50% by mass to 5.0% by mass with respect to the total mass of the photosensitive layer.

The photosensitive layer may contain an aliphatic thiol compound, or an aromatic thiol compound other than the heterocyclic compound. Hereinafter, the aliphatic thiol compound will be described.

In a case where the photosensitive layer contains an aliphatic thiol compound, an ene-thiol reaction of the aliphatic thiol compound with the radically polymerizable compound having an ethylenically unsaturated group suppresses a cure shrinkage of the formed film and relieves stress.

As the aliphatic thiol compound, a monofunctional aliphatic thiol compound or a polyfunctional aliphatic thiol compound (that is, bi- or higher functional aliphatic thiol compound) is preferable. Among the above-described compounds, as the aliphatic thiol compound, from the viewpoint of adhesiveness of the formed pattern (particularly, adhesiveness after exposure), a polyfunctional aliphatic thiol compound is preferable. In the present disclosure, the “polyfunctional aliphatic thiol compound” refers to an aliphatic compound having two or more thiol groups (also referred to as “mercapto groups”) in a molecule.

As the polyfunctional aliphatic thiol compound, a low-molecular-weight compound having a molecular weight of 100 or more is preferable. Specifically, the molecular weight of the polyfunctional aliphatic thiol compound is more preferably 100 to 1,500 and still more preferably 150 to 1,000.

From the viewpoint of adhesiveness of the formed pattern, for example, the number of functional groups in the polyfunctional aliphatic thiol compound is preferably 2 to 10, more preferably 2 to 8, and still more preferably 2 to 6.

Examples of the polyfunctional aliphatic thiol compound include trimethylolpropane tris(3-mercaptobutyrate), 1,4-bis(3-mercaptobutyryloxy)butane, pentaerythritol tetrakis(3-mercaptobutyrate), 1,3,5-tris(3-mercaptobutyryloxyethyl)-1,3,5-triazine-2,4,6(1H,3H,5H)-trione, trimethylolethane tris(3-mercaptobutyrate), tris[(3-mercaptopropionyloxy)ethyl]isocyanurate, trimethylolpropane tris(3-mercaptopropionate), pentaerythritol tetrakis(3-mercaptopropionate), tetraethylene glycol bis(3-mercaptopropionate), dipentaerythritol hexakis(3-mercaptopropionate), ethylene glycol bisthiopropionate, 1,2-ethanedithiol, 1,3-propanedithiol, 1,6-hexamethylenedithiol, 2,2′-(ethylenedithio)diethanethiol, meso-2,3-dimercaptosuccinic acid, and di(mercaptoethyl) ether.

Among the above-described compounds, the polyfunctional aliphatic thiol compound is preferably at least one compound selected from the group consisting of trimethylolpropane tris(3-mercaptobutyrate), 1,4-bis(3-mercaptobutyryloxy)butane, and 1,3,5-tris(3-mercaptobutyryloxyethyl)-1,3,5-triazine-2,4,6(1H,3H,5H)-trione.

Examples of the monofunctional aliphatic thiol compound include 1-octanethiol, 1-dodecanethiol, β-mercaptopropionic acid, methyl-3-mercaptopropionate, 2-ethylhexyl-3-mercaptopropionate, n-octyl-3-mercaptopropionate, methoxybutyl-3-mercaptopropionate, and stearyl-3-mercaptopropionate.

In a case where the photosensitive layer contains an aliphatic thiol compound, or an aromatic thiol compound other than the heterocyclic compound, so that a layer containing silver is adjacent to the photosensitive layer (that is, in a case where the layer containing silver is adjacent to the resin pattern), deterioration and migration of the silver can be suppressed.

The photosensitive layer may include only one kind of the aliphatic thiol compound or the aromatic thiol compound other than the heterocyclic compound, or may include two or more kinds thereof.

In a case where the photosensitive layer contains the aliphatic thiol compound or the aromatic thiol compound, a content of the aliphatic thiol compound is preferably 0.1% by mass or more, more preferably 0.1% by mass to 30% by mass, still more preferably 0.2% by mass to 20% by mass, and particularly preferably 0.5% by mass to 10% by mass with respect to the total mass of the photosensitive layer.

From the viewpoint of hardness of a cured film to be obtained and pressure-sensitive adhesiveness of an uncured film to be obtained, the photosensitive layer preferably contains a thermal crosslinking compound. Hereinafter, the thermal crosslinking compound will be described.

In the present disclosure, a thermal crosslinking compound having an ethylenically unsaturated group, which will be described later, is not treated as the ethylenically unsaturated compound, but is treated as the thermal crosslinking compound.

Examples of the thermal crosslinking compound include an epoxy compound, an oxetane compound, a methylol compound, and a blocked isocyanate compound. Among these, from the viewpoint of hardness of a cured film to be obtained and pressure-sensitive adhesiveness of an uncured film to be obtained, a blocked isocyanate compound is preferable.

Since the blocked isocyanate compound reacts with a hydroxy group and a carboxy group, for example, in a case where at least one of the polymer or the radically polymerizable compound having an ethylenically unsaturated group has at least one of a hydroxy group or a carboxy group, hydrophilicity of the formed film tends to decrease, and the function as a protective film tends to be strengthened. The blocked isocyanate compound refers to a “compound having a structure in which the isocyanate group of isocyanate is protected (so-called masked) with a blocking agent”.

A dissociation temperature of the blocked isocyanate compound is not particularly limited, but is preferably 100° C. to 160° C. and more preferably 130° C. to 150° C. The dissociation temperature of blocked isocyanate means “temperature at an endothermic peak accompanied with a deprotection reaction of blocked isocyanate, in a case where the measurement is performed by differential scanning calorimetry (DSC) analysis using a differential scanning calorimeter”. As the differential scanning calorimeter, for example, a differential scanning calorimeter (model: DSC6200) manufactured by Seiko Instruments Inc. can be suitably used. However, the differential scanning calorimeter is not limited thereto.

Examples of the blocking agent having a dissociation temperature of 100° C. to 160° C. include an active methylene compound [diester malonates (dimethyl malonate, diethyl malonate, di-n-butyl malonate, di-2-ethylhexyl malonate, and the like)], and an oxime compound (compound having a structure represented by —C(═N—OH)— in a molecule, such as formaldoxime, acetoaldoxime, acetoxime, methyl ethyl ketoxime, and cyclohexanoneoxime). Among these, from the viewpoint of storage stability, the blocking agent having a dissociation temperature of 100° C. to 160° C. is preferably, for example, at least one selected from oxime compounds.

From the viewpoint of improving brittleness of the film and improving the adhesion to the object to be transferred, for example, the blocked isocyanate compound preferably has an isocyanurate structure. The blocked isocyanate compound having an isocyanurate structure can be obtained, for example, by isocyanurate-forming and protecting hexamethylene diisocyanate. Among the blocked isocyanate compounds having an isocyanurate structure, a compound having an oxime structure using an oxime compound as a blocking agent is preferable from the viewpoint that the dissociation temperature can be easily set in a preferred range and the development residue can be easily reduced, as compared with a compound having no oxime structure.

The blocked isocyanate compound may have a polymerizable group. The polymerizable group is not particularly limited, and a known polymerizable group can be used, and a radically polymerizable group is preferable. Examples of the polymerizable group include a (meth)acryloxy group, a (meth)acrylamide group, an ethylenically unsaturated group such as styryl group, and an epoxy group such as a glycidyl group. Among these, as the polymerizable group, an ethylenically unsaturated group is preferable, a (meth)acryloxy group is more preferable, and an acryloxy group still more preferable.

As the blocked isocyanate compound, a commercially available product can be used. Examples of the commercially available product of the blocked isocyanate compound include Karenz (registered trademark) AOI-BM, Karenz (registered trademark) MOI-BM, Karenz (registered trademark) MOI-BP, and the like (all of which are manufactured by SHOWA DENKO K.K.), and block-type DURANATE series (for example, DURANATE (registered trademark) TPA-B80E, DURANATE (registered trademark) WT32-B75P, and the like manufactured by Asahi Kasei Corporation).

As the blocked isocyanate compound, a compound having the following structure can also be used.

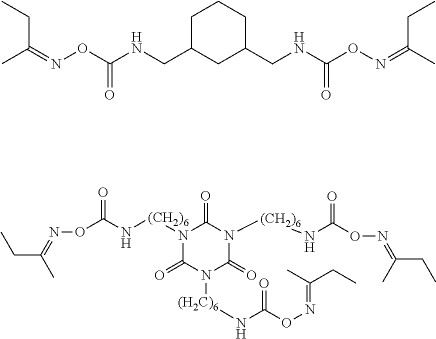

The thermal crosslinking compound may be used alone or in combination of two or more kinds thereof.

In a case where the photosensitive layer contains the thermal crosslinking compound, a content of the thermal crosslinking compound is preferably 1% by mass to 50% by mass and more preferably 5% by mass to 30% by mass with respect to the total mass of the photosensitive layer.

The photosensitive layer may contain a surfactant. Hereinafter, the surfactant will be described.

Examples of the surfactant include surfactants described in paragraph [0017] of JP4502784B and paragraphs [0060] to [0071] of JP2009-237362A. As the surfactant, a nonionic surfactant, a fluorine-based surfactant, or a silicone-based surfactant is preferable.

Examples of the nonionic surfactant include glycerol, trimethylolpropane, trimethylolethane, an ethoxylate and propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters, PLURONIC L10, L31, L61, L62, 10R5, 17R2, and 25R2 (all of which are manufactured by BASF SE), TETRONIC 304, 701, 704, 901, 904, and 150R1 (all of which are manufactured by BASF SE), SOLSPERSE 20000 (manufactured by Lubrizol Corporation), NCW-101, NCW-1001, and NCW-1002 (all of which are manufactured by FUJIFILM Wako Pure Chemical Corporation), PIONIN D-6112, D-6112-W, and D-6315 (all of which are manufactured by Takemoto Oil & Fat Co., Ltd.), and OLFINE E1010 and SURFYNOL 104, 400, and 440 (all of which are manufactured by Nissin Chemical Co., Ltd.).

Examples of a commercially available product of the fluorine-based surfactant include: MEGAFACE (registered trademark) F-171, F-172, F-173, F-176, F-177, F-141, F-142, F-143, F-144, F-437, F-475, F-477, F-479, F-482, F-551-A, F-552, F-554, F-555-A, F-556, F-557, F-558, F-559, F-560, F-561, F-565, F-563, F-568, F-575, F-780, EXP, MFS-330, MFS-578, MFS-579, MFS-586, MFS-587, R-41, R-41-LM, R-01, R-40, R-40-LM, RS-43, TF-1956, RS-90, R-94, RS-72-K, and DS-21 (all of which are manufactured by DIC Corporation); FLUORAD FC430, FC431, and FC171 (all of which are manufactured by Sumitomo 3M Ltd.); SURFLON (registered trademark) S-382, SC-101, SC-103, SC-104, SC-105, SC-1068, SC-381, SC-383, S-393, and KH-40 (all of which are manufactured by Asahi Glass Co., Ltd.); and POLYFOX PF636, PF656, PF6320, PF6520, and PF7002 (all of which are manufactured by OMNOVA Solutions Inc.); FTERGENT 710FL, 710FM, 610FM, 601AD, 601ADH2, 602A, 215M, 245F, 251, 212M, 250, 209F, 222F, 208G, 710LA, 710FS, 730LM, 650AC, 681, and 683 (all of which are manufactured by NEOS COMPANY LIMITED).

In addition, as the fluorine-based surfactant, an acrylic compound, which has a molecular structure having a functional group containing a fluorine atom and in which, by applying heat to the molecular structure, the functional group containing a fluorine atom is broken to volatilize a fluorine atom, can also be suitably used. Examples of such a fluorine-based surfactant include MEGAFACE (registered trademark) DS series manufactured by DIC Corporation (The Chemical Daily (Feb. 22, 2016) and Nikkei Business Daily (Feb. 23, 2016)), for example, MEGAFACE (registered trademark) DS-21.

In addition, as the fluorine-based surfactant, a polymer of a fluorine atom-containing vinyl ether compound having a fluorinated alkyl group or a fluorinated alkylene ether group, and a hydrophilic vinyl ether compound is also preferably used.

In addition, as the fluorine-based surfactant, a block polymer can also be used.

In addition, as the fluorine-based surfactant, a fluorine-containing polymer compound including a constitutional unit derived from a (meth)acrylate compound having a fluorine atom and a constitutional unit derived from a (meth)acrylate compound having 2 or more (preferably 5 or more) alkyleneoxy groups (preferably ethyleneoxy groups or propyleneoxy groups) can also be preferably used.

In addition, as the fluorine-based surfactant, a fluorine-containing polymer having an ethylenically unsaturated bond-containing group in the side chain can also be used. Examples thereof include MEGAFACE (registered trademark) RS-101, RS-102, RS-718K, and RS-72-K (all manufactured by DIC Corporation).

As the fluorine-based surfactant, from the viewpoint of improving environmental suitability, a surfactant derived from a substitute material for a compound having a linear perfluoroalkyl group having 7 or more carbon atoms, such as perfluorooctanoic acid (PFOA) and perfluorooctanesulfonic acid (PFOS), is preferable.

Examples of the silicone-based surfactant include a linear polymer consisting of a siloxane bond and a modified siloxane polymer with an organic group introduced in the side chain or the terminal.

Specific examples of the silicone-based surfactant include DOWSIL 8032 ADDITIVE, TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all of which are manufactured by Dow Corning Toray Co., Ltd.), X-22-4952, X-22-4272, X-22-6266, KF-351A, K354L, KF-355A, KF-945, KF-640, KF-642, KF-643, X-22-6191, X-22-4515, KF-6004, KP-341, KF-6001, and KF-6002 (all of which are manufactured by Shin-Etsu Chemical Co., Ltd.), F-4440, TSF-4300, TSF-4445, TSF-4460, and TSF-4452 (all of which are manufactured by Momentive Performance Materials Co., Ltd.), and BYK307, BYK323, and BYK330 (all of which are manufactured by BYK Chemie).

The surfactant may be used alone or in combination of two or more kinds thereof.

In a case where the photosensitive layer contains the surfactant, a content of the surfactant is preferably 0.01% by mass to 3.0% by mass, more preferably 0.01% by mass to 1.0% by mass, and still more preferably 0.05% by mass to 0.80% by mass with respect to the total mass of the photosensitive layer.

The photosensitive layer may contain a polymerization inhibitor. Hereinafter, the polymerization inhibitor will be described.

The polymerization inhibitor means a compound having a function of delaying or prohibiting a polymerization reaction. As the polymerization inhibitor, for example, a known compound used as a polymerization inhibitor can be used.

Examples of the polymerization inhibitor include phenothiazine compounds such as phenothiazine, bis-(1-dimethylbenzyl)phenothiazine, and 3,7-dioctylphenothiazine; hindered phenolic compounds such as bis[3-(3-tert-butyl-4-hydroxy-5-methylphenyl)propionic acid][ethylene bis(oxyethylene)], 2,4-bis[(laurylthio)methyl]-o-cresol, 1,3,5-tris(3,5-di-t-butyl-4-hydroxybenzyl), 1,3,5-tris(4-t-butyl-3-hydroxy-2,6-dimethylbenzyl), 2,4-bis-(n-octylthio)-6-(4-hydroxy-3,5-di-t-butylanilino)-1,3,5-triazine, and pentaerythritol tetrakis3-(3,5-di-tert-butyl-4-hydroxyphenyl)propionate; nitroso compounds or a salt thereof, such as 4-nitrosophenol, N-nitrosodiphenylamine, N-nitrosocyclohexylhydroxylamine, and N-nitrosophenylhydroxylamine; quinone compounds such as methylhydroquinone, t-butylhydroquinone, 2,5-di-t-butylhydroquinone, and 4-benzoquinone; phenolic compounds such as 4-methoxyphenol, 4-methoxy-1-naphthol, and t-butylcatechol; and metal salt compounds such as copper dibutyldithiocarbamate, copper diethyldithiocarbamate, manganese diethyldithiocarbamate, and manganese diphenyldithiocarbamate. Among these, as the polymerization inhibitor, at least one selected from the group consisting of a phenothiazine compound, a nitroso compound or a salt thereof, and a hindered phenolic compound is preferable, and phenothiazine, bis[3-(3-tert-butyl-4-hydroxy-5-methylphenyl)propionic acid][ethylene bis(oxyethylene)], 2,4-bis[(laurylthio)methyl]-o-cresol, 1,3,5-tris(3,5-di-t-butyl-4-hydroxybenzyl), p-methoxyphenol, or an aluminum salt of N-nitrosophenylhydroxylamine is more preferable.

The polymerization inhibitor may be used alone or in combination of two or more kinds thereof.

In a case where the photosensitive layer contains the polymerization inhibitor, a content of the polymerization inhibitor is preferably 0.001% by mass to 5.0% by mass, more preferably 0.01% by mass to 3.0% by mass, and still more preferably 0.02% by mass to 2.0% by mass with respect to the total mass of the photosensitive layer. The content of the polymerization inhibitor is preferably 0.005% by mass to 5.0% by mass, more preferably 0.01% by mass to 3.0% by mass, and still more preferably 0.01% by mass to 1.0% by mass with respect to the total mass of the polymerizable compound.

The photosensitive layer may contain a hydrogen donating compound. Hereinafter, the hydrogen donating compound will be described.

The hydrogen donating compound has a function of further improving sensitivity of the photopolymerization initiator to actinic ray, suppressing inhibition of polymerization of the polymerizable compound by oxygen, or the like. Examples of the hydrogen donating compound include amines and an amino acid compound.

Examples of the amines include compounds described in M. R. Sander et al., “Journal of Polymer Society,” Vol. 10, page 3173 (1972), JP1969-020189B (JP-S44-020189B), JP1976-082102A (JP-S51-082102A), JP1977-134692A (JP-S52-134692A), JP1984-138205A (JP-S59-138205A), JP1985-084305A (JP-S60-084305A), JP1987-018537A (JP-S62-018537A), JP1989-033104A (JP-S64-033104A), and Research Disclosure 33825. More specific examples thereof include 4,4′-bis(diethylamino)benzophenone, tris(4-dimethylaminophenyl)methane (another name: Leucocrystal Violet), triethanolamine, p-dimethylaminobenzoic acid ethyl ester, p-formyldimethylaniline, and p-methylthiodimethylaniline. Among these, as the amines, at least one selected from the group consisting of 4,4′-bis(diethylamino)benzophenone and tris(4-dimethylaminophenyl)methane is preferable.

Examples of the amino acid compound include N-phenylglycine, N-methyl-N-phenylglycine, and N-ethyl-N-phenylglycine. Among these, as the amino acid compound, N-phenylglycine is preferable.

In addition, examples of the hydrogen donating compound also include an organic metal compound described in JP1973-042965B (JP-S48-042965B) (tributyl tin acetate and the like), a hydrogen donor described in JP1980-034414B (JP-S55-034414B), and a sulfur compound described in JP1994-308727A (JP-H6-308727A) (trithiane and the like).

The hydrogen donating compound may be used alone or in combination of two or more kinds thereof.

In a case where the photosensitive layer contains the hydrogen donating compound, from the viewpoint of improving a curing rate by balancing the polymerization growth rate and chain transfer, a content of the hydrogen donating compound is preferably 0.01% by mass to 10.0% by mass, more preferably 0.01% by mass to 8.0% by mass, and still more preferably 0.03% by mass to 5.0% by mass with respect to the total mass of the photosensitive layer.

The photosensitive layer may contain a predetermined amount of impurities. Hereinafter, the impurities will be described.

Examples of the impurities include sodium, potassium, magnesium, calcium, iron, manganese, copper, aluminum, titanium, chromium, cobalt, nickel, zinc, tin, halogen, and ions of these. Among these, halide ion, sodium ion, and potassium ion are easily mixed as impurities, so that the following content is preferable.

A content of the impurities in the photosensitive layer is preferably 80 ppm or less, more preferably 10 ppm or less, and still more preferably 2 ppm or less on a mass basis. A content of impurities in the photosensitive layer may be 1 ppb or more or 0.1 ppm or more on a mass basis.

Examples of a method of setting the impurities in the above-described range include selecting a raw material having a low content of impurities as a raw material for the photosensitive layer, preventing the impurities from being mixed in a case of forming the photosensitive layer, and washing and removing the impurities. By such a method, the amount of impurities can be kept within the above-described range.

The impurities can be quantified by a known method such as inductively coupled plasma (ICP) emission spectroscopy, atomic absorption spectroscopy, and ion chromatography.

In the photosensitive layer, it is preferable that the content of compounds such as benzene, formaldehyde, trichlorethylene, 1,3-butadiene, carbon tetrachloride, chloroform, N,N-dimethylformamide, N,N-dimethylacetamide, and hexane is low in each layer. The content of these compounds in the photosensitive layer is preferably 100 ppm or less, more preferably 20 ppm or less, and still more preferably 4 ppm or less on a mass basis. The lower limit thereof may be 10 ppb or more or 100 ppb or more on a mass basis. The content of these compounds can be suppressed in the same manner as in the above-described metal as impurities. In addition, the compounds can be quantified by a known measurement method.

From the viewpoint of reliability and laminating property, the content of water in the photosensitive layer is preferably 0.01% to 1.0% by mass and more preferably 0.05% to 0.5% by mass.

The photosensitive layer may contain a residual monomer of each constitutional unit in the above-described alkali-soluble resin. Hereinafter, the residual monomer will be described.

From the viewpoint of patterning properties and reliability, a content of the residual monomer is preferably 5,000 ppm by mass or less, more preferably 2,000 ppm by mass or less, and still more preferably 500 ppm by mass or less with respect to the total mass of the alkali-soluble resin. The lower limit thereof is not particularly limited, but is preferably 1 ppm by mass or more, and more preferably 10 ppm by mass or more. From the viewpoint of patterning properties and reliability, the residual monomer of each constitutional unit in the alkali-soluble resin is preferably 3,000 ppm by mass or less, more preferably 600 ppm by mass or less, and still more preferably 100 ppm by mass or less with respect to the total mass of the photosensitive layer. The lower limit thereof is not particularly limited, but is preferably 0.1 ppm by mass or more, and more preferably 1 ppm by mass or more.

It is preferable that the amount of residual monomer of the monomer in a case of synthesizing the alkali-soluble resin by the polymer reaction is also within the above-described range. For example, in a case where glycidyl acrylate is reacted with a carboxylic acid side chain to synthesize the alkali-soluble resin, the content of glycidyl acrylate is preferably within the above-described range. The amount of residual monomers can be measured by a known method such as liquid chromatography and gas chromatography.

The photosensitive layer may contain a component other than the above-mentioned components (hereinafter, also referred to as “other components”). Hereinafter, the other components will be described.

Examples of the other components include a colorant, an antioxidant, and particles (for example, metal oxide particles). In addition, examples of the other components also include other additives described in paragraphs [0058] to [0071] of JP2000-310706A.

The photosensitive layer may contain a trace amount of a colorant (pigment, dye, and the like), but for example, from the viewpoint of transparency, it is preferable that the photosensitive layer does not substantially contain the colorant. In a case where the photosensitive layer contains the colorant, a content of the colorant is preferably less than 1% by mass, and more preferably less than 0.1% by mass with respect to the total mass of the photosensitive layer.

Examples of the antioxidant include 3-pyrazolidones such as 1-phenyl-3-pyrazolidone (another name; phenidone), 1-phenyl-4,4-dimethyl-3-pyrazolidone, and 1-phenyl-4-methyl-4-hydroxymethyl-3-pyrazolidone; polyhydroxybenzenes such as hydroquinone, catechol, pyrogallol, methylhydroquinone, and chlorohydroquinone; paramethylaminophenol, paraaminophenol, parahydroxyphenylglycine, and paraphenylenediamine. Among these, as the antioxidant, 3-pyrazolidones are preferable, and 1-phenyl-3-pyrazolidone is more preferable. In a case where the photosensitive layer contains the antioxidant, a content of the antioxidant is preferably 0.001% by mass or more, more preferably 0.005% by mass or more, and still more preferably 0.01% by mass or more with respect to the total mass of the photosensitive layer. The upper limit thereof is not particularly limited, but is preferably 1% by mass or less.

As the particles, metal oxide particles are preferable. The metal of the metal oxide particles also includes semimetal such as B, Si, Ge, As, Sb, or Te. From the viewpoint of transparency of the cured film, for example, an average primary particle diameter of the particles is preferably 1 to 200 nm and more preferably 3 to 80 nm. The average primary particle diameter of the particles is calculated by measuring particle diameters of 200 random particles using an electron microscope and arithmetically averaging the measurement result. In a case where the shape of the particle is not a spherical shape, the longest side is set as the particle diameter. In a case where the photosensitive layer contains the particles, the photosensitive layer may contain only one kind of particles, or may contain two or more kinds of particles having different metal types, sizes, and the like. It is preferable that the photosensitive layer does not contain the particles, or in a case where the photosensitive layer contains the particles, a content of the particles is more than 0% by mass and 35% by mass or less with respect to the total mass of the photosensitive layer; it is more preferable that the photosensitive layer does not contain the particles, or in a case where the photosensitive layer contains the particles, a content of the particles is more than 0% by mass and 10% by mass or less with respect to the total mass of the photosensitive layer; it is still more preferable that the photosensitive layer does not contain the particles, or in a case where the photosensitive layer contains the particles, a content of the particles is more than 0% by mass and 5% by mass or less with respect to the total mass of the photosensitive layer; it is particularly preferable that the photosensitive layer does not contain the particles, or in a case where the photosensitive layer contains the particles, a content of the particles is more than 0% by mass and 1% by mass or less with respect to the total mass of the photosensitive layer; and it is most preferable that the photosensitive layer does not contain the particles.

Next, a method of disposing the photosensitive layer on the base material will be described. In the disposing step, the method of disposing the photosensitive layer on the base material is not limited. In the disposing step, the photosensitive layer may be formed on the base material, or a photosensitive layer prepared in advance may be disposed on the base material. In the former method, the photosensitive layer can be disposed on the base material by, for example, applying the photosensitive composition onto the base material, and then drying the photosensitive composition as necessary. In the latter method, for example, a photosensitive layer and a temporary support can be arranged in this order on the base material by laminating a transfer film including a temporary support and the photosensitive layer with the base material. In the disposing step, it is preferable to dispose the photosensitive layer on the base material by using the transfer film.

The component of the photosensitive composition is selected from the components of the photosensitive layer described above, according to composition of the target photosensitive layer. The above-described matters relating to the components of the photosensitive layer are applied to the aspects of the photosensitive composition by reading “photosensitive layer” as “photosensitive composition” and reading “total mass of the photosensitive layer” as “total mass of photosensitive composition”. Preferred components of the photosensitive composition are the same as the preferred components of the photosensitive layer described above.

The photosensitive composition may contain a solvent as necessary. As the solvent, an organic solvent is preferable. Examples of the organic solvent include methyl ethyl ketone, propylene glycol monomethyl ether, propylene glycol monomethyl ether acetate (another name: 1-methoxy-2-propyl acetate), diethylene glycol ethyl methyl ether, cyclohexanone, methyl isobutyl ketone, ethyl lactate, methyl lactate, caprolactam, n-propanol, and 2-propanol. In addition, as the solvent, an organic solvent (high-boiling-point solvent) having a boiling point of 180° C. to 250° C. can also be used, as necessary. The solvent may be used alone or in combination of two or more kinds thereof.

The total solid content of the photosensitive composition is preferably 5% by mass to 80% by mass, more preferably 5% by mass to 40% by mass, and still more preferably 5% by mass to 30% by mass with respect to the total mass of the photosensitive composition. That is, a content of the solvent in the photosensitive composition is preferably 20% by mass to 95% by mass, more preferably 60% by mass to 95% by mass, and still more preferably 70% by mass to 95% by mass with respect to the total mass of the photosensitive composition.

For example, from the viewpoint of coating properties, a viscosity of the photosensitive composition at 25° C. is preferably 1 mPa s to 50 mPa s, more preferably 2 mPa s to 40 mPa s, and still more preferably 3 mPa s to 30 mPa s. The viscosity is measured using a viscometer. As the viscometer, for example, a viscometer (product name: VISCOMETER TV-22) manufactured by Toki Sangyo Co., Ltd. can be suitably used. However, the viscometer is not limited to the above-described viscometer.

For example, from the viewpoint of coating properties, a surface tension of the photosensitive composition at 25° C. is preferably 5 mN/m to 100 mN/m, more preferably 10 mN/m to 80 mN/m, and still more preferably 15 mN/m to 40 mN/m. The surface tension is measured using a tensiometer. As the tensiometer, for example, a tensiometer (product name: Automatic Surface Tensiometer CBVP-Z) manufactured by Kyowa Interface Science Co., Ltd. can be suitably used. However, the tensiometer is not limited to the above-described tensiometer.

Examples of a method for applying the photosensitive composition include a printing method, a spray coating method, a roll coating method, a bar coating method, a curtain coating method, a spin coating method, and a die coating method (that is, a slit coating method).

As a method for drying the photosensitive composition, heat drying or vacuum drying is preferable. The “drying” means removing at least a part of the solvent contained in the composition. Examples of the drying method include natural drying, heat drying, and vacuum drying. The above-described methods can be adopted alone or in combination of two or more thereof. The drying temperature is preferably 80° C. or higher and more preferably 90° C. or higher. In addition, the upper limit value thereof is preferably 130° C. or lower and more preferably 120° C. or lower. The drying can be performed by continuously changing the temperature. The drying time is preferably 20 seconds or more, more preferably 40 seconds or more, and still more preferably 60 seconds or more. In addition, the upper limit value thereof is not particularly limited, but is preferably 600 seconds or less, and more preferably 300 seconds or less.

The transfer film used in the disposing step preferably includes a temporary support and a photosensitive layer in this order. Hereinafter, the transfer film will be described. However, in the following description, the aspects of the photosensitive layer in the transfer film are the same as the aspects of the photosensitive layer described above, and thus are omitted.

The transfer film preferably includes a temporary support. The temporary support is a member which supports the photosensitive layer, and is finally removed by a peeling treatment. The temporary support may be a monolayer structure or a multilayer structure.

The temporary support is preferably a film and more preferably a resin film. As the temporary support, a film which has flexibility and does not generate significant deformation, contraction, or stretching under pressure or under pressure and heating is preferable. Examples of the above-described film include a polyethylene terephthalate film (for example, a biaxial stretching polyethylene terephthalate film), a polymethylmethacrylate film, a cellulose triacetate film, a polystyrene film, a polyimide film, and a polycarbonate film. Among these, as the temporary support, a polyethylene terephthalate film is preferable. In addition, it is preferable that the film used as the temporary support does not have deformation such as wrinkles or scratches.

From the viewpoint that pattern exposure through the temporary support can be performed, the temporary support preferably has high transparency, and the transmittance at 313 nm, 365 nm, 405 nm, and 436 nm is preferably 60% or more, more preferably 70% or more, still more preferably 80% or more, and most preferably 90% or more. Examples of a preferred value of the transmittance include 87%, 92%, and 98%.

From the viewpoint of pattern formability during pattern exposure through the temporary support and transparency of the temporary support, it is preferable that a haze of the temporary support is small. Specifically, a haze value of the temporary support is preferably 2% or less, more preferably 0.5% or less, and still more preferably 0.1% or less.

From the viewpoint of pattern formability during pattern exposure through the temporary support and transparency of the temporary support, it is preferable that the number of fine particles, foreign substances, and defects included in the temporary support is small. The number of fine particles, foreign substances, and defects having a diameter of 1 m or more in the temporary support is preferably 50 pieces/10 mm² or less, more preferably 10 pieces/10 mm² or less, still more preferably 3 pieces/10 mm² or less, and particularly preferably 0 pieces/10 mm².

A thickness of the temporary support is preferably 5 m to 200 m. From the viewpoint of ease of handling and general-purpose properties, the thickness of the temporary support is more preferably 5 m to 150 m, still more preferably 5 m to 50 m, and particularly preferably m to 25 m. The thickness of the temporary support is represented by an arithmetic average of thicknesses at five points, measured by cross-sectional observation using a scanning electron microscope (SEM).

In order to improve adhesiveness between the temporary support and the photosensitive layer, a surface of the temporary support facing the photosensitive layer may be surface-modified by ultraviolet irradiation, corona discharge, plasma, or the like. In a case of being surface-modified by ultraviolet irradiation, an exposure amount is preferably 10 mJ/cm² to 2,000 mJ/cm² and more preferably 50 mJ/cm² to 1,000 mJ/cm². Examples of a light source for the ultraviolet irradiation include a low pressure mercury lamp, a high pressure mercury lamp, a ultra-high pressure mercury lamp, a carbon arc lamp, a metal halide lamp, a xenon lamp, a chemical lamp, an electrodeless discharge lamp, and a light emitting diode (LED), all of which emit a light in a wavelength range of 150 nm to 450 nm. As long as the amount of light irradiated is within the above-described range, the lamp output and the illuminance are not limited.

Examples of the temporary support include a biaxial stretching polyethylene terephthalate film having a film thickness of 16 m, a biaxial stretching polyethylene terephthalate film having a film thickness of 12 m, and a biaxial stretching polyethylene terephthalate film having a film thickness of 9 am.

The temporary support may be a recycled product. Examples of the recycled product include films obtained washing used films and the like into chips and using the chips as a material. Specific examples of the recycled product include Ecouse series of Toray Industries, Inc.

A preferred aspect of the temporary support is described in, for example, paragraphs [0017] and [0018] of JP2014-085643A, paragraphs [0019] to [0026] of JP2016-027363A, paragraphs [0041] to [0057] of WO2012/081680A, and paragraphs [0029] to [0040] of WO2018/179370A, the contents of which are incorporated herein by reference.

From the viewpoint of imparting handleability, a layer (lubricant layer) including fine particles may be provided on the surface of the temporary support. The lubricant layer may be provided on one surface of the temporary support, or on both surfaces thereof. A diameter of the particles included in the lubricant layer is preferably 0.05 to 0.8 m. In addition, a film thickness of the lubricant layer is preferably 0.05 to 1.0 m.

Examples of a commercially available product of the temporary support include LUMIRROR (registered trademark) 16KS40, LUMIRROR (registered trademark) 16FB40, LUMIRROR (registered trademark) #38-U48, LUMIRROR (registered trademark) #75-U34, and LUMIRROR (registered trademark) #25-T60 (all of which are manufactured by Toray Industries, Inc.); and COSMOSHINE (registered trademark) A4100, COSMOSHINE (registered trademark) A4300, COSMOSHINE (registered trademark) A8300, COSMOSHINE (registered trademark) A4160, and COSMOSHINE (registered trademark) A4360 (all of which are manufactured by TOYOBO Co., Ltd.).

It is preferable that the transfer film further includes a refractive index adjusting layer. Specifically, it is preferable that the transfer film includes the temporary support, the photosensitive layer, and the refractive index adjusting layer in this order. As the refractive index adjusting layer, a known refractive index adjusting layer can be adopted.

Examples of a material contained in the refractive index adjusting layer include a polymer, a polymerizable compound, a metal salt, and particles. A method for controlling a refractive index of the refractive index adjusting layer is not particularly limited, and examples thereof include a method using a resin having a predetermined refractive index alone, a method using the polymer and particles, and a method using a composite body of the polymer and a resin. Examples of the polymer include the polymers described above as the component of the photosensitive layer. Examples of the polymerizable compound include the polymerizable compounds described above as the component of the photosensitive layer. Examples of the particles include metal oxide particles and metal particles. The type of the metal oxide particles is not particularly limited, and examples thereof include known metal oxide particles. The metal of the metal oxide particles also includes semimetal such as B, Si, Ge, As, Sb, or Te.

Specifically, as the metal oxide particles, at least one selected from the group consisting of zirconium oxide particles (ZrO₂ particles), Nb₂O₅ particles, titanium oxide particles (TiO₂ particles), silicon dioxide particles (SiO₂ particles), and composite particles thereof is preferable. Among these, for example, from the viewpoint that it is easy to adjust the refractive index, the metal oxide particles are more preferably at least one selected from the group consisting of zirconium oxide particles and titanium oxide particles.

Examples of a commercially available product of the metal oxide particles include calcined zirconium oxide particles (manufactured by CIK-Nano Tek., product name: ZRPGM15WT %-F04), calcined zirconium oxide particles (manufactured by CIK-Nano Tek., product name: ZRPGM15WT %-F74), calcined zirconium oxide particles (manufactured by CIK-Nano Tek., product name: ZRPGM15WT %-F75), calcined zirconium oxide particles (manufactured by CIK-Nano Tek., product name: ZRPGM15WT %-F76), zirconium oxide particles (NanoUse OZ-S30M, manufactured by Nissan Chemical Corporation), and zirconium oxide particles (NanoUse OZ-S30K, manufactured by Nissan Chemical Corporation).

From the viewpoint of transparency of the cured film, for example, an average primary particle diameter of the particles is preferably 1 nm to 200 nm and more preferably 3 nm to 80 nm. The average primary particle diameter of the particles is calculated by measuring particle diameters of 200 random particles using an electron microscope and arithmetically averaging the measurement result. In a case where the shape of the particle is not a spherical shape, the longest side is set as the particle diameter.

The particles may be used alone or in combination of two or more kinds thereof.

A content of the particles in the refractive index adjusting layer is preferably 1% by mass to 95% by mass, more preferably 20% by mass to 90% by mass, and still more preferably 40% by mass to 85% by mass with respect to the total mass of the refractive index adjusting layer. In a case where titanium oxide is used as the metal oxide particles, the content of the titanium oxide particles is preferably 1% by mass to 95% by mass, more preferably 20% by mass to 90% by mass, and still more preferably 40% by mass to 85% by mass with respect to the total mass of the refractive index adjusting layer.

It is preferable that the refractive index of the refractive index adjusting layer is higher than the refractive index of the photosensitive layer. A refractive index of the refractive index adjusting layer is preferably 1.50 or more, more preferably 1.55 or more, still more preferably 1.60 or more, and particularly preferably 1.65 or more. The refractive index of the refractive index adjusting layer is preferably 2.10 or less, more preferably 1.85 or less, and still more preferably 1.78 or less.

A thickness of the refractive index adjusting layer is preferably 50 nm to 500 nm, more preferably 55 nm to 110 nm, and still more preferably 60 nm to 100 nm. The thickness of the refractive index adjusting layer is represented by an arithmetic average of thicknesses at five points, measured by cross-sectional observation using a scanning electron microscope (SEM).

The refractive index adjusting layer is produced, for example, by using a composition for forming a refractive index adjusting layer. The composition for forming a refractive index adjusting layer preferably contains various components forming the above-described refractive index adjusting layer and a solvent. In the composition for forming a refractive index adjusting layer, a suitable range of the content of each component with respect to the total solid content of the composition is the same as the suitable range of the content of each component with respect to the total mass of the refractive index adjusting layer described above.

The solvent is not particularly limited as long as it can dissolve or disperse the components included in the refractive index adjusting layer, and at least one selected from the group consisting of water and a water-miscible organic solvent is preferable, water or a mixed solvent of water and a water-miscible organic solvent is more preferable. Examples of the water-miscible organic solvent include an alcohol having 1 to 3 carbon atoms, acetone, ethylene glycol, and glycerin, and an alcohol having 1 to 3 carbon atoms is preferable and methanol or ethanol is more preferable. The solvent may be used alone, or in combination of two or more kinds thereof. A content of the solvent is preferably 50 to 2,500 parts by mass, more preferably 50 to 1,900 parts by mass, and still more preferably 100 to 900 parts by mass with respect to 100 parts by mass of the total solid content of the composition.

The refractive index adjusting layer may be produced by applying the composition for forming a refractive index adjusting layer. Examples of the applying method include slit coating, spin coating, curtain coating, and inkjet coating.

It is preferable that the transfer film further includes a protective film. Specifically, it is preferable that the transfer film includes the temporary support, the photosensitive layer, and the protective film in this order. It is also preferable that the transfer film includes the temporary support, the photosensitive layer, the refractive index adjusting layer, and the protective film in this order.

As the protective film, a resin film having heat resistance and solvent resistance can be used, and examples thereof include polyolefin films such as a polypropylene film and a polyethylene film, polyester films such as a polyethylene terephthalate film, polycarbonate films, and polystyrene films. In addition, as the protective film, a resin film formed of the same material as in the above-described temporary support may be used. Among these, as the protective film, a polyolefin film is preferable, a polypropylene film or a polyethylene film is more preferable, and a polyethylene film is still more preferable.

A thickness of the protective film is preferably 1 m to 100 m, more preferably 5 m to 50 m, still more preferably 5 m to 40 m, and particularly preferably 15 m to 30 m. The thickness of the protective film is preferably 1 m or more in terms of excellent mechanical hardness, and is preferably 100 m or less in terms of relatively low cost. The thickness of the protective film is represented by an arithmetic average of thicknesses at five points, measured by cross-sectional observation using a scanning electron microscope (SEM).

The number of fisheyes with a diameter of 80 m or more in the protective film is preferably 5 pieces/m² or less. The “fisheye” means that, in a case where a material is hot-melted, kneaded, extruded, biaxially stretched, cast or the like to produce a film, foreign substances, undissolved substances, oxidatively deteriorated substances, and the like of the material are incorporated into the film. The number of particles having a diameter of 3 m or more included in the protective film is preferably 30 particles/mm² or less, more preferably 10 particles/mm² or less, and still more preferably 5 particles/mm² or less. With regard to the reduction of the number of fisheyes, it is possible to suppress defects caused by ruggedness due to the particles included in the protective film being transferred to the photosensitive layer or a layer in contact with the protective film, such as the photosensitive layer.

From the viewpoint of imparting take-up property, the arithmetic average roughness Ra on a surface of the protective film opposite to the surface in contact with the photosensitive layer is preferably 0.01 μm or more, more preferably 0.02 μm or more, and still more preferably 0.03 μm or more. The above-described roughness Ra is preferably less than 0.50 μm, more preferably 0.40 μm or less, and still more preferably 0.30 μm or less.

From the viewpoint of suppressing defects during transfer, the surface roughness Ra on the surface of the protective film in contact with the photosensitive layer is preferably 0.01 μm or more, more preferably 0.02 μm or more, and still more preferably 0.03 μm or more. The above-described roughness Ra is preferably less than 0.50 μm, more preferably 0.40 μm or less, and still more preferably 0.30 μm or less.

For example, the protective film is introduced into the transfer film by laminating the protective film with the photosensitive layer or the refractive index adjusting layer. The lamination of the protective film with the photosensitive layer or the refractive index adjusting layer is carried out using, for example, a known laminator. Examples of the laminator include a vacuum laminator and an auto-cut laminator. The laminator preferably includes a heatable roller. The laminator preferably has a function of pressurization and heating in the lamination.

The method of laminating the transfer film with the base material is not limited. The lamination of the transfer film with the base material is carried out using, for example, a known laminator. Examples of the laminator include a vacuum laminator and an auto-cut laminator. The bonding between the transfer film and the base material is preferably carried out under pressurization and heating conditions. The temperature is preferably 70° C. to 130° C. In a case where the transfer film includes the protective film, the protective film is peeled off before the lamination of the transfer film with the base material.

(Exposing Step)

In the exposing step, the photosensitive layer is exposed in a patterned manner. According to the exposing step, an exposed portion and a non-exposed portion are formed on the photosensitive layer. A positional relationship between the exposed portion and the non-exposed portion is not limited. The positional relationship between the exposed portion and the non-exposed portion is determined, for example, according to a shape of the target resin pattern. In the exposing step, light for exposing the photosensitive layer in a patterned manner may be emitted along a direction from the photosensitive layer to the base material or a direction from the base material to the photosensitive layer.

A light source in the exposing step is selected, for example, from light sources which emit light having a wavelength capable of causing a chemical change in the photosensitive layer (for example, 365 nm or 405 nm). A main wavelength of the light is preferably 365 nm. The “main wavelength” means a wavelength having the highest intensity. Examples of the light source include various lasers, a light emitting diode (LED), an ultra-high pressure mercury lamp, a high pressure mercury lamp, and a metal halide lamp.

An exposure amount in the exposing step is preferably 5 mJ/cm² to 200 mJ/cm² and more preferably 10 mJ/cm² to 200 mJ/cm².

Preferred aspects of the light source, exposure amount, and exposure method in the exposing step are described, for example, in paragraphs [0146] and [0147] of WO2018/155193A. The contents of the above-described publication are incorporated in the present specification by reference.

(Developing Step)

In the developing step, an exposed portion or a non-exposed portion of the photosensitive layer is removed using a developer containing at least one component selected from the group consisting of a sodium ion and a potassium ion to form a resin pattern. In a case where the photosensitive layer is of a negative tone, the non-exposed portion of the photosensitive layer is usually removed by the developer, and the resin pattern is formed by the exposed portion of the photosensitive layer. In a case where the photosensitive layer is of a positive tone, the exposed portion of the photosensitive layer is usually removed by the developer, and the resin pattern is formed by the non-exposed portion of the photosensitive layer.

It is confirmed by an ion chromatography method that the developer contains at least one component selected from the group consisting of a sodium ion and a potassium ion. The developer containing the at least one component selected from the group consisting of a sodium ion and a potassium ion is produced, for example, by mixing a solvent with at least one component selected from the group consisting of a sodium compound and a potassium compound. Examples of the solvent include water. Examples of the sodium compound include a compound which generates sodium ions in the solvent (for example, a sodium salt). Examples of the sodium salt include sodium hydroxide, sodium carbonate, and sodium hydrogen carbonate. Examples of the potassium compound include a compound which generates potassium ions in the solvent (for example, a potassium salt). Examples of the potassium salt include potassium hydroxide, potassium carbonate, and potassium hydrogen carbonate.

The temperature of the developer is preferably 22° C. to 33° C., more preferably 24° C. to 30° C., and still more preferably 26° C. In a case where the temperature of the developer is 22° C. or higher, development defects are reduced. In a case where the temperature of the developer is 33° C. or lower, the depth of presence of the specific component in the resin pattern is likely to be adjusted to 3.0 m or less.

The treatment time in the developing step is preferably 22 seconds to 50 seconds, more preferably 22 seconds to 40 seconds, still more preferably 22 seconds to 30 seconds, and particularly preferably 25 seconds. In a case where the treatment time is 22 seconds or more, development defects are reduced. In a case where the treatment time is 50 seconds or less, the depth of presence of the specific component in the resin pattern is likely to be adjusted to 3.0 m or less.

Examples of a method of the developing step include puddle development, shower development, spin development, and dip development. Examples of a preferred development method include development methods described in paragraph [0195] of WO2015/093271A.

(Washing Step)

In the washing step, the resin pattern is washed with water. In the washing step, in addition to that residue after the development and developer adhering to the base material and the resin pattern can be removed, for example, depending on the water temperature and the treatment time, the depth of presence of the specific component in the resin pattern can be adjusted.

In the washing step, the resin pattern may be washed by immersion in water. In the washing step, the resin pattern may be washed with jetted water. In the washing step, constituent elements other than the resin pattern may be washed together with the resin pattern.

The water temperature in the washing step is preferably 21° C. to 35° C., more preferably 21° C. to 30° C., still more preferably 21° C. to 25° C., and most preferably 21° C. In a case where the water temperature is 21° C. or higher, the depth of presence of the specific component in the resin pattern is likely to be adjusted to 0.3 m or more. In a case where the water temperature is 35° C. or lower, the depth of presence of the specific component in the resin pattern is likely to be adjusted to 3.0 m or less.

The treatment time in the washing step is preferably 21 seconds to 50 seconds, more preferably 22 seconds to 40 seconds, still more preferably 23 seconds to 30 seconds, and particularly preferably 25 seconds. In a case where the treatment time is 21 seconds or more, the depth of presence of the specific component in the resin pattern is likely to be adjusted to 0.3 m or more. In a case where the treatment time is 50 seconds or less, the depth of presence of the specific component in the resin pattern is likely to be adjusted to 3.0 m or less.

Examples of the water which is used in the washing step include pure water and ultrapure water. In the washing step, a mixed solvent of water and a solvent other than the water may be used as necessary. In a case where the mixed solvent is used in the washing step, the above-described “water temperature” is read as “temperature of the mixed solvent”.

(Standing step)

In the standing step, the base material and the resin pattern are allowed to stand. The standing step can greatly contribute to the adjustment of the depth of presence of the specific component in the resin pattern. In the standing step, for example, the depth of presence of the specific component in the resin pattern can be adjusted according to the standing time. The standing means that time elapses without performing post-process. Therefore, in a case where the post-process is not performed on the base material and the resin pattern, the standing step includes transportation, and change in ambient temperature and humidity accompanying the transportation. Examples of the post-process include post-exposure and post-baking, which will be described later, and OCA laminating treatment for device formation.

The standing time in the standing step is preferably 1 hour to 72 hours, more preferably 15 hours to 48 hours, and still more preferably 24 hours to 48 hours. In a case where the standing time is 1 hour or more, the depth of presence of the specific component in the resin pattern is likely to be adjusted to 0.3 m or more. In a case where the standing time is 72 hours or less, the depth of presence of the specific component in the resin pattern is likely to be adjusted to 3.0 m or less.

The temperature (for example, the ambient temperature) in the standing step is preferably 15° C. to 35° C., and more preferably 20° C. to 30° C.

The relative humidity in the standing step is preferably 40% RH to 70% RH, and more preferably 50% RH to 60% RH.

(Other Steps)

The manufacturing method of a laminate according to the embodiment of the present disclosure may further include other steps as necessary. Examples of the other steps include a peeling step, a post-exposing step, and a post-baking step. However, the other steps are not limited to the above-described specific examples. The other steps may be selected from known steps depending on the application of the laminate.

In the peeling step, the temporary support is peeled off. It is preferable that the peeling step is performed between the disposing step and the exposing step, or between the exposing step and the developing step. As a peeling step, for example, a mechanism similar to peeling mechanism of a cover film, described in paragraphs [0161] and [0162] of JP2010-072589A, is used.

In the post-exposing step, the resin pattern is exposed. It is preferable that the post-exposing step is performed after the standing step. An exposure amount in the post-exposing step is preferably 100 mJ/cm² to 5,000 mJ/cm² and more preferably 200 mJ/cm² to 3,000 mJ/cm².

In the post-baking step, the resin pattern is heated. In a case where the manufacturing method of a laminate according to the embodiment of the present disclosure includes the post-exposing step and the post-baking step, it is preferable that the post-baking step is performed after the post-exposing step. The temperature in the post-baking step is preferably 80° C. to 250° C., and more preferably 90° C. to 160° C. The treatment time in the post-baking step is preferably 1 minute to 180 minutes, and more preferably 10 minutes to 60 minutes.

### EXAMPLES

Hereinafter, the present disclosure will be described in detail according to Examples. However, the present disclosure is not limited to the following Examples. The materials, the amounts and proportions of the materials used, the details of treatments, the procedure of treatments, and the like in the following Examples may be appropriately modified as long as the gist of the present disclosure is maintained. “part” and “%” are based on mass unless otherwise specified. A weight-average molecular weight is a weight-average molecular weight obtained by performing polystyrene conversion of a value measured by gel permeation chromatography (GPC). An acid value is a theoretical acid value.

### Example 1

(Synthesis of Polymer P-1)

113.5 g of propylene glycol monomethyl ether was charged into a flask and heated to 90° C. under a nitrogen stream. To the flask, a solution in which 172 g of styrene, 4.7 g of methyl methacrylate, and 112.1 g of methacrylic acid had been dissolved in 30 g of propylene glycol monomethyl ether and a solution in which 27.6 g of a polymerization initiator V-601 (manufactured by FUJIFILM Wako Pure Chemical Corporation) had been dissolved in 57.7 g of propylene glycol monomethyl ether was simultaneously added dropwise over 3 hours. After the dropwise addition, 2.5 g of V-601 was added three times every hour. Thereafter, the reaction was continued for another 3 hours. The reaction solution was diluted with 160.7 g of propylene glycol monomethyl ether acetate and 233.3 g of propylene glycol monomethyl ether. The reaction solution was heated to 100° C. under an air stream, and 1.8 g of tetraethylammonium bromide and 0.86 g of p-methoxyphenol were added thereto, and then 71.9 g of glycidyl methacrylate (Blemmer G manufactured by NOF Corporation) was added dropwise thereto over 20 minutes. The obtained mixture was reacted at 100° C. for 7 hours to obtain a solution containing a polymer P-1 represented by the following chemical formula (hereinafter, may be referred to as “P-1 solution”). The concentration of solid contents of the obtained solution was 36.2% by mass. The amount of residual monomer measured by gas chromatography was less than 0.1% by mass with respect to the solid content of the polymer in any of the monomers.

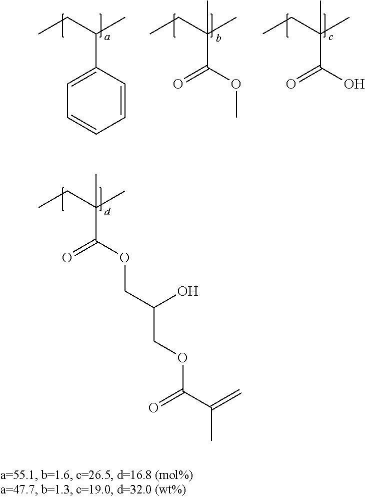

Properties of the polymer P-1 were as follows. The weight-average molecular weight (Mw) and number-average molecular weight (Mn) are standard polystyrene-equivalent molecular weights measured by gel permeation chromatography (GPC).
Weight-average molecular weight (Mw): 18,000
Number-average molecular weight (Mn): 7,800
Dispersity: 2.3
Acid value: 124 mgKOH/g

(Synthesis of Blocked Isocyanate Compound Q-1)

Under a nitrogen stream, 453 g of butanone oxime (manufactured by Idemitsu Kosan Co., Ltd.) was dissolved in 700 g of methyl ethyl ketone. To the obtained mixture, 500 g of 1,3-bis(isocyanatomethyl)cyclohexane (mixture of cis-trans isomer, manufactured by Mitsui Chemicals Inc., TAKENATE 600) was added dropwise over 1 hour under ice-cooling, and the reaction was performed for another 1 hour. Thereafter, the temperature was raised to 40° C. and the reaction was performed for 1 hour. It was confirmed by ¹H-nuclear magnetic resonance (NMR) and high performance liquid chromatography (HPLC) that the reaction was completed to obtain a methyl ethyl ketone solution of a blocked isocyanate compound Q-1. The blocked isocyanate compound Q-1 is represented by the following chemical formula.

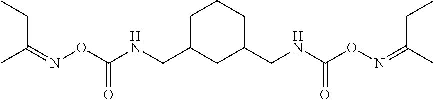 [SMILES: CC/C(C)=N\OC(=O)NCC1CCCC(CNC(=O)O/N=C(/C)CC)C1]

(Preparation of Blocked Isocyanate Compound Q-2)

As a blocked isocyanate compound Q-2, “DURANATE TPA-B80E” (manufactured by Asahi Kasei Corporation) was prepared.

(Preparation of Photosensitive Composition A-1)

A photosensitive composition A-1 was prepared by mixing the components (1) to (5) shown below, methyl ethyl ketone, and 1-methoxy-2-propyl acetate. The unit of the content of the components (1) to (5) shown below is a part by mass expressed in terms of solid contents. The amount of methyl ethyl ketone and 1-methoxy-2-propyl acetate added was adjusted so that the concentration of solid contents of the photosensitive composition A-1 was 25% by mass. The amount of methyl ethyl ketone added was adjusted so that the proportion of methyl ethyl ketone in the solvent in the photosensitive composition A-1 was 60% by mass.

(1) Polymer
P-1 solution: 49.04 parts by mass

(2) Polymerizable Compound
Tricyclodecane dimethanol diacrylate (A-DCP, manufactured by Shin-Nakamura Chemical Co., Ltd.): 9.13 parts by mass
Monomer having a carboxy group (ARONIX T02349, manufactured by Toagosei Co., Ltd.): 3.04 parts by mass
Acrylic monomer (A-NOD-N, manufactured by Shin-Nakamura Chemical Co., Ltd.): 2.79 parts by mass
Acrylic monomer (A-DPH, manufactured by Shin-Nakamura Chemical Co., Ltd.): 17.28 parts by mass

(3) Polymerization Initiator
1-[9-ethyl-6-(2-methylbenzoyl)-9H-carbazole-3-yl]ethanone-1-(0-acetyloxime) (OXE-02, manufactured by BASF): 0.37 parts by mass
1-(biphenyl-4-yl)-2-methyl-2-morpholinopropan-1-one (APi-307, manufactured by Shenzhen UV-ChemTech Co., Ltd.): 0.74 parts by mass

(4) Blocked Isocyanate
Blocked isocyanate compound Q-1: 12.50 parts by mass
Blocked isocyanate compound Q-2: 2.97 parts by mass

(5) Additive
N-phenylglycine (manufactured by Tokyo Chemical Industry Co., Ltd.): 0.10 parts by mass
Benzimidazole (manufactured by Tokyo Chemical Industry Co., Ltd.): 0.52 parts by mass
Isonicotinamide (manufactured by Tokyo Chemical Industry Co., Ltd.): 0.13 parts by mass
XIRAN EF-40 (manufactured by KAWAHARA PETROCHEMICAL CO., LTD.): 1.20 parts by mass
MEGAFACE (registered trademark) F551A (manufactured by DIC Corporation): 0.19 parts by mass

(Production of Transfer Film)

As a temporary support, a 16 μm-thick polyethylene terephthalate film (LUMIRROR 16KS40, manufactured by Toray Industries, Inc.) was prepared. The photosensitive composition A-1 was applied onto the temporary support using a slit-shaped nozzle, and by volatilizing the solvent in a drying zone at 100° C., a photosensitive layer having a film thickness of 5.5 μm was formed. A protective film (LUMIRROR 16KS40, manufactured by Toray Industries, Inc.) was pressure-bonded onto the photosensitive layer to produce a transfer film.

(Production of Substrate)

By the following procedure, a substrate including a base material (cycloolefin polymer film), a transparent film, and a transparent electrode pattern (ITO) in this order was obtained.

As the base material, a cycloolefin polymer film (thickness: 38 μm, refractive index: 1.53) was prepared. Using a high-frequency oscillator, the base material was subjected to a corona discharge treatment under the following conditions.
Output voltage: 100%
Output: 250 W
Electrode: wire electrode having a diameter of 1.2 mm
Electrode length: 240 mm
Distance between work electrodes: 1.5 mm
Treatment time: 3 seconds

Next, a composition containing components shown in Table 1 (numerical value of each component in Table 1 is the content (part by mass)) was applied to the base material using a slit-shaped nozzle, and then the composition was irradiated with ultraviolet rays (integrated light intensity: 300 mJ/cm²) and dried at approximately 110° C. to form a transparent film (refractive index: 1.60, thickness: 80 nm).

TABLE 1

| Material | Part by mass |
|---|---|
| ZrO₂: ZR-010 manufactured by Solar Corporation | 2.08 |
| KARAYAD DPHA (dipentaerythritol hexaacrylate, | 0.11 |
| manufactured by Nippon Kayaku Co., Ltd.) | |
| Urethane-based monomer: NK OLIGO UA-32P, | 0.11 |
| manufactured by Shin-Nakamura Chemical Co., Ltd. | |
| VISCOAT #802 (mixture of tripentaerythritol acrylate and | 0.36 |
| mono-, di-, or polypentaerythritol acrylate, manufactured by | |
| Osaka Organic Chemical Industry Ltd.) | |
| Polymer having structure represented by Formula P-25, | 0.85 |
| Mw: 35,000 | |
| Photoradical polymerization initiator: 2-benzyl-2- | 0.03 |
| dimethylamino-1-(4-morpholinylphenyl)-butanone | |
| (Irgacure (registered trademark) 369, manufactured by | |
| BASF SE) | |
| Photopolymerization initiator: KAYACURE DETX-S | 0.03 |
| (manufactured by Nippon Kayaku Co., Ltd., alkylthio | |
| xanthone) | |
| MEGAFACE F-551 (manufactured by DIC Corporation) | 0.01 |
| 1-Methoxy-2-propyl acetate | 38.73 |
| Methyl ethyl ketone | 57.69 |
| Total (part by mass) | 100 |

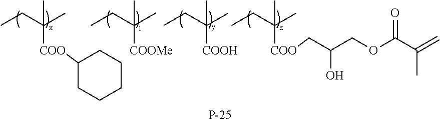

x:l:y:z = 46:2:20:32 (mol %)

An indium tin oxide (ITO) film having a thickness of 40 nm and a refractive index of 1.82 was formed on the transparent film by DC magnetron sputtering, and a transparent electrode pattern was formed on the transparent film by patterning the formed ITO film by photoetching. The formation of the ITO film and the patterning of the ITO film were carried out by the methods described in paragraphs [0119] to [0122] of JP2014-10814A.

Production of Laminate

After peeling off the protective film of the transfer film, the transfer film was laminated to the substrate so that the photosensitive layer covered the transparent film and the transparent electrode pattern. The lamination was performed using a vacuum laminator manufactured by MCK under conditions of a temperature of the base material (that is, the cycloolefin polymer film): 40° C., a rubber roller temperature: 100° C., a linear pressure: 3 N/cm, and a transportation speed: 4 m/min. Next, using a proximity type exposure machine (manufactured by Hitachi High-Tech Electronics Engineering Co., Ltd.) including an ultra-high pressure mercury lamp, an exposure mask (quartz exposure mask having a pattern for forming an overcoat) and the temporary support were closely attached, and the photosensitive layer was exposed in a patterned manner with an exposure amount of 150 mJ/cm² (measured with i-rays) through the temporary support. The exposed sample was allowed to stand in an environment of 23° C. and 55% RH (relative humidity) for 24 hours, and then the temporary support was peeled off and developed with a 1.0% by mass sodium carbonate aqueous solution (liquid temperature: 25° C.) for 25 seconds. The developed sample was washed with water by spraying pure water at 21° C. for 25 seconds from an ultra-high pressure washing nozzle. After removing water adhering to the sample by blowing air, the sample was allowed to stand in an environment of 23° C. and 55% RH (relative humidity) for 24 hours. The resin pattern was exposed with an exposure amount of 400 mJ/cm² (measured value with i-rays) using a post-exposure machine (manufactured by Ushio, Inc.) having a high pressure mercury lamp (post-exposure). Finally, post-baking treatment was carried out at 145° C. for 30 minutes, thereby obtaining a laminate including the base material, the transparent film, the transparent electrode pattern, and the resin pattern in this order. The resin pattern was a cured substance of the photosensitive composition A-1.

### Example 2

A laminate was obtained by the same procedure as in Example 1, except that the temperature of pure water in the water washing treatment was changed to 25° C.

### Example 3

A laminate was obtained by the same procedure as in Example 1, except that the temperature of pure water in the water washing treatment was changed to 25° C., and the time of the water washing treatment was changed to 45 seconds.

### Example 4

A laminate was obtained by the same procedure as in Example 1, except that the standing time after the water washing treatment was changed to 3 hours.

### Example 5

A laminate was obtained by the same procedure as in Example 1, except that the temperature of pure water in the water washing treatment was changed to 25° C., the time of the water washing treatment was changed to 45 seconds, and the standing time after the water washing treatment was changed to 72 hours.

### Example 6

A laminate was obtained by the same procedure as in Example 1, except that the standing time after the water washing treatment was changed to 48 hours.

### Example 7

A laminate was obtained by the same procedure as in Example 6, except that the polymer P-1 was changed to a polymer P-2 represented by the following chemical formula. In the following chemical formula, a numerical value added to each constitutional unit represents mol %.

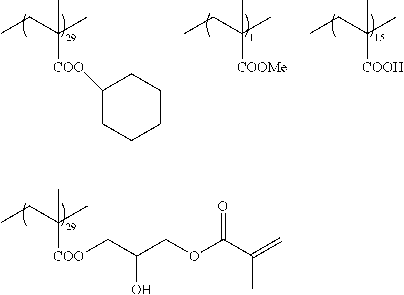

Properties of the polymer P-2 were as follows. The weight-average molecular weight (Mw) and number-average molecular weight (Mn) are standard polystyrene-equivalent molecular weights measured by gel permeation chromatography (GPC).
Acid value: 95 mgKOH/g
Weight-average molecular weight (Mw): 27,000
Number-average molecular weight (Mn): 15,000

### Example 8

A laminate was obtained by the same procedure as in Example 6, except that the components of the photosensitive composition were changed according to the description in Table 2.

### Example 9

A laminate was obtained by the same procedure as in Example 6, except that the polymer P-1 was changed to a polymer P-3. The polymer P-3 was a random copolymer of benzyl methacrylate and methacrylic acid. A molar ratio of “benzyl methacrylate/methacrylic acid” in the polymer P-3 was 72/28. The weight-average molecular weight (Mw) of the polymer P-3 was 37,000.

### Example 10

A laminate was obtained by the same procedure as in Example 6, except that the polymerizable compound in the photosensitive composition A-1 was changed to the following polymerizable compound.
NK ESTER BPE-500 (polymerizable compound, 2,2-bis(4-(methacryloxypentethoxy)phenyl)propane, manufactured by Shin-Nakamura Chemical Co., Ltd.): 22.5 parts by mass
NK Ester BPE-200 (polymerizable compound, 2,2-bis(4-(methacryloxydiethoxy)phenyl)propane, manufactured by Shin-Nakamura Chemical Co., Ltd.): 10.0 parts by mass
NK ESTER A-TMPT (polymerizable compound, trimethylolpropane triacrylate, manufactured by Shin-Nakamura Chemical Co., Ltd.): 10.0 parts by mass

### Example 11

A laminate was obtained by the same procedure as in Example 6, except that the components of the photosensitive composition were changed according to the description in Table 2.

### Example 12

A laminate was obtained by the same procedure as in Example 6, except that the components of the photosensitive composition were changed according to the description in Table 2.

### Example 13

A laminate was obtained by the same procedure as in Example 6, except that the thickness of the photosensitive layer was changed to 3.3 m.

### Example 14

A laminate was obtained by the same procedure as in Example 6, except that the thickness of the photosensitive layer was changed to 10.9 m.

### Example 15

A laminate was obtained by the same procedure as in Example 1, except that the developer in the development treatment was changed to 1% by mass potassium carbonate aqueous solution.

### Example 16

A laminate was obtained by the same procedure as in Example 4, except that the developer in the development treatment was changed to 1% by mass potassium carbonate aqueous solution.

### Example 17

A laminate was obtained by the same procedure as in Example 5, except that the developer in the development treatment was changed to 1% by mass potassium carbonate aqueous solution.

### Examples 18 to 20

A laminate was obtained by the same procedure as in Example 6, except that the photosensitive layer was formed of a photosensitive composition containing components described in Table 3. In the preparation of the photosensitive composition, methyl ethyl ketone and 1-methoxy-2-propyl acetate were appropriately added as solvents, and the amount of the solvents was adjusted so that a proportion of the methyl ethyl ketone in all solvents of the photosensitive composition was 50% by mass and the concentration of solid contents of the photosensitive composition was 20% by mass.

### Examples 21 and 22

A laminate was obtained by the same procedure as in Example 6, except that the photosensitive layer was formed of a photosensitive composition containing components described in Table 4.

### Examples 23 to 25

A laminate was obtained by the same procedure as in Example 6, except that the photosensitive layer was formed of a photosensitive composition containing components described in Table 5.

### Comparative Example 1

A laminate was obtained by the same procedure as in Example 6, except that the conditions of the development treatment and the conditions of the water washing treatment were changed to the following conditions.
Temperature of developer: 20° C.
Time of development treatment: 20 seconds
Temperature of pure water in water washing treatment: 20° C.
Time of water washing treatment: 20 seconds
Standing time after water washing treatment: 0 hours

### Comparative Example 2

A laminate was obtained by the same procedure as in Example 6, except that the conditions of the development treatment and the conditions of the water washing treatment were changed to the following conditions.
Temperature of developer: 35° C.
Time of development treatment: 60 seconds
Temperature of pure water in water washing treatment: 40° C.
Time of water washing treatment: 60 seconds
Standing time after water washing treatment: 80 hours

<Depth of Presence of Sodium Ion or Potassium Ion>

Using SIMS5 manufactured by IONTOF GmbH and Ar⁺ cluster sputtering gun, distribution of sodium ion or potassium ion in a depth direction of the resin pattern was measured. Specifically, with regard to the resin pattern formed by the development treatment using 1% by mass sodium carbonate aqueous solution, the sodium ion was detected, and with regard to the resin pattern formed by the development treatment using 1% by mass potassium carbonate aqueous solution, the potassium ion was detected. The depth direction analysis was performed along a direction from the resin pattern toward the base material. Specifically, the sodium ion or the potassium ion was detected by TOF-SIMS while sputtering the measurement target with the Ar⁺ cluster sputtering gun. On the assumption that an intensity of the target component (that is, the sodium ion or the potassium ion) detected on the surface of the resin pattern was 100%, a sputtering time when the intensity of the target component first reaches 90% was converted to a depth (that is, a distance from the surface of the resin pattern to the point where the intensity of the target component first reached 90%) based on a sputtering rate. The above-described “depth” was measured at any three points which were points where the edge lift did not occur in the pattern, were separated by 10 m or more in a plane direction of the base material from the point where the edge lift occurred, and were separated by 100 m or more from each other, and then an arithmetic average value of three measured values was defined as the “depth of presence”. The measurement results are shown in Tables 2 to 5.

<Evaluation>

The following items were evaluated using the laminates obtained in Examples and Comparative Examples. The evaluation results are shown in Tables 2 to 5.

(Scratch Resistance)

Using a spherical diamond scratch needle having a tip diameter of 75 m, the resin pattern was scratched with a load of 10 g and a length of 5 cm. The degree of occurrence of scratches in the resin pattern was confirmed, and the scratch resistance was evaluated according to the following standard A to D. A or B is a level at which there is no problem in practical use, and A is preferable.
A: no scratches were observed visually or in observation with an optical microscope.
B: slight scratches were observed in the observation with an optical microscope.
C: scratches were observed in the observation with an optical microscope, but no scratches were observed visually.
D: scratches were remarkably observed visually.

(Edge Lift)

Using a scanning electron microscope, a cross section near the edge of the resin pattern in the laminate was observed. A width of the edge lift of the resin pattern (specifically, a length of a portion where the edge of the resin pattern was lifted) was measured, and the edge lift was evaluated according to the following standard A to D. A or B is a level at which there is no problem in practical use, and A is preferable.
A: no edge lift was observed.
B: the width of the edge lift was 0.1 m or more and less than 5.0 m.
C: the width of the edge lift was 5.0 m or more and less than 10.0 m.
D: the width of the edge lift was 10.0 μm or more.

TABLE 2

| | | | | Example | | | | | |
|---|---|---|---|---|---|---|---|---|---|
| | | | | 1 | 2 | 3 | 4 | 5 | 6 |
| Photosensitive | Type | | | A-1 | A-1 | A-1 | A-1 | A-1 | A-1 |
| composition | | | Type | P-1 | P-1 | P-1 | P-1 | P-1 | P-1 |
| | Polymer | | Content | 49.04 | 49.04 | 49.04 | 49.04 | 49.04 | 49.04 |
| | Polymerizable | A-DCP | Content | 9.13 | 9.13 | 9.13 | 9.13 | 9.13 | 9.13 |
| | compound | TO2349 | Content | 3.04 | 3.04 | 3.04 | 3.04 | 3.04 | 3.04 |
| | | A-NOD-N | Content | 2.79 | 2.79 | 2.79 | 2.79 | 2.79 | 2.79 |
| | | A-DPH | Content | 17.28 | 17.28 | 17.28 | 17.28 | 17.28 | 17.28 |
| | | BPE-500 | Content | — | — | — | — | — | — |
| | | BPE-200 | Content | — | — | — | — | — | — |
| | | A-TMPT | Content | — | — | — | — | — | — |
| | Blocked | Q-1 | Content | 12.50 | 12.50 | 12.50 | 12.50 | 12.50 | 12.50 |
| | isocyanate | Q-2 | Content | 2.97 | 2.97 | 2.97 | 2.97 | 2.97 | 2.97 |
| | compound | | | | | | | | |
| | Polymerization | OXE-02 | Content | 0.37 | 0.37 | 0.37 | 0.37 | 0.37 | 0.37 |
| | initiator | OXE-03 | Content | — | — | — | — | — | — |
| | | Api-307 | Content | 0.74 | 0.74 | 0.74 | 0.74 | 0.74 | 0.74 |
| Resin pattern | Thickness of resin pattern (μm) | | | 5.0 | 5.0 | 5.0 | 5.0 | 5.0 | 5.0 |
| | Depth of presence of sodium ion | | | 1.0 | 1.3 | 1.6 | 0.3 | 3.0 | 2.0 |
| | or potassium ion (μm) | | | | | | | | |
| Evaluation | Scratch resistance | | | A | A | A | B | A | A |
| | Edge lift | | | A | A | A | A | B | A |
| | | | | Example | | | | | |
| | | | | 7 | 8 | 9 | 10 | 11 | 12 |
| Photosensitive | Type | | | A-2 | A-3 | A-4 | A-5 | A-7 | A-8 |
| composition | | | Type | P-2 | P-2 | P-3 | P-1 | P-1 | P-1 |
| | Polymer | | Content | 49.04 | 55.04 | 49.04 | 59.3 | 64.51 | 49.04 |
| | Polymerizable | A-DCP | Content | 9.13 | 6.13 | 9.13 | 9.13 | 9.13 | 9.13 |
| | compound | TO2349 | Content | 3.04 | 3.04 | 3.04 | — | 3.04 | 3.04 |
| | | A-NOD-N | Content | 2.79 | 2.79 | 2.79 | — | 2.79 | 2.79 |
| | | A-DPH | Content | 17.28 | 14.28 | 17.28 | — | 17.28 | 17.28 |
| | | BPE-500 | Content | — | — | — | 22.5 | — | — |
| | | BPE-200 | Content | — | — | — | 10.0 | — | — |
| | | A-TMPT | Content | — | — | — | 10.0 | — | — |
| | Blocked | Q-1 | Content | 12.50 | 12.50 | 12.50 | 12.50 | — | 12.50 |
| | isocyanate | Q-2 | Content | 2.97 | 2.97 | 2.97 | 2.97 | — | 2.97 |
| | compound | | | | | | | | |
| | Polymerization | OXE-02 | Content | 0.37 | 0.37 | 0.37 | 0.37 | 0.37 | — |
| | initiator | OXE-03 | Content | — | — | — | — | — | 0.50 |
| | | Api-307 | Content | 0.74 | 0.74 | 0.74 | 0.74 | 0.74 | 0.61 |
| Resin pattern | Thickness of resin pattern (μm) | | | 5.0 | 5.0 | 5.0 | 5.0 | 5.0 | 5.0 |
| | Depth of presence of sodium ion | | | 2.3 | 2.3 | 2.3 | 2.2 | 2.0 | 2.0 |
| | or potassium ion (μm) | | | | | | | | |
| Evaluation | Scratch resistance | | | A | A | B | A | A | A |
| | Edge lift | | | A | A | A | A | A | A |
| | | | | | Example | | | | |
| | | | | | 13 | 14 | 15 | 16 | 17 |
| Photosensitive | Type | | | | A-1 | A-1 | A-1 | A-1 | A-1 |
| composition | | | Type | | P-1 | P-1 | P-1 | P-1 | P-1 |
| | Polymer | | Content | | 49.04 | 49.04 | 49.04 | 49.04 | 49.04 |
| | Polymerizable | A-DCP | Content | | 9.13 | 9.13 | 9.13 | 9.13 | 9.13 |
| | compound | TO2349 | Content | | 3.04 | 3.04 | 3.04 | 3.04 | 3.04 |
| | | A-NOD-N | Content | | 2.79 | 2.79 | 2.79 | 2.79 | 2.79 |
| | | A-DPH | Content | | 17.28 | 17.28 | 17.28 | 17.28 | 17.28 |
| | | BPE-500 | Content | | — | — | — | — | — |
| | | BPE-200 | Content | | — | — | — | — | — |
| | | A-TMPT | Content | | — | — | — | — | — |
| | Blocked | Q-1 | Content | | 12.50 | 12.50 | 12.50 | 12.50 | 12.50 |
| | isocyanate | Q-2 | Content | | 2.97 | 2.97 | 2.97 | 2.97 | 2.97 |
| | compound | | | | | | | | |
| | Polymerization | OXE-02 | Content | | 0.37 | 0.37 | 0.37 | 0.37 | 0.37 |
| | initiator | OXE-03 | Content | | — | — | — | — | — |
| | | Api-307 | Content | | 0.74 | 0.74 | 0.74 | 0.74 | 0.74 |

| Resin pattern | Thickness of resin pattern (μm) | 3.0 | 10 | 5.0 | 5.0 | 5.0 |
|---|---|---|---|---|---|---|
| | Depth of presence of sodium ion | 2.0 | 2.0 | 1.0 | 0.3 | 3.0 |
| | or potassium ion (μm) | | | | | |
| Evaluation | Scratch resistance | A | A | A | B | A |
| | Edge lift | A | A | A | A | B |
| | | | | | Comparative | |
| | | | | | Example | |
| | | | | | 1 | 2 |

| Photosensitive | Type | | | A-1 | A-1 |
|---|---|---|---|---|---|
| composition | | | Type | P-1 | P-1 |
| | Polymer | | Content | 49.04 | 49.04 |
| | Polymeriz- | A-DCP | Content | 9.13 | 9.13 |
| | able | TO2349 | Content | 3.04 | 3.04 |
| | compound | A-NOD-N | Content | 2.79 | 2.79 |
| | | A-DPH | Content | 17.28 | 17.28 |
| | | BPE-500 | Content | — | — |
| | | BPE-200 | Content | — | — |
| | | A-TMPT | Content | — | — |
| | Blocked | Q-1 | Content | 12.50 | 12.50 |
| | isocyanate | Q-2 | Content | 2.97 | 2.97 |
| | compound | | | | |
| | Polymeriz- | OXE-02 | Content | 0.37 | 0.37 |
| | ation | OXE-03 | Content | — | — |
| | initiator | Api-307 | Content | 0.74 | 0.74 |

| | | | |
|---|---|---|---|
| Resin pattern | Thickness of resin pattern (μm) | 5.0 | 5.0 |
| | Depth of presence of sodium ion | 0.1 | 3.5 |
| | or potassium ion (μm) | C | A |
| Evaluation | Scratch resistance | A | C |
| | Edge lift | | |

In Table 2, the unit of the content of the component described in the column of “Photosensitive composition” is part by mass expressed in terms of solid contents. The “Depth of presence of sodium ion or potassium ion” in Examples 1 to 14 and Comparative Examples 1 and 2 specifically means the depth of presence of the sodium ion. The “Depth of presence of sodium ion or potassium ion” in Examples 15 to 17 specifically means the depth of presence of the potassium ion.

TABLE 3

| | | | Example | Example | Example |
|---|---|---|---|---|---|
| | | | 18 | 19 | 20 |
| Photosensitive | Polymer | Polymer A-1 | — | 55.00 | — |
| composition | | monomer ratio = styrene/methacrylic acid/methyl methacrylate/benzyl | | | |
| | | methacrylate = 45/25/5/25 (% by mass) | | | |
| | | Mw = 50,000 | | | |
| | | Polymer A-2 | 50.00 | — | — |
| | | monomer ratio = styrene/methacrylic acid/methyl methacrylate = | | | |
| | | 52/29/23 (% by mass) | | | |
| | | Mw = 60,000 | | | |
| | | Polymer A-3 | — | — | 52.00 |
| | | monomer ratio = styrene/methacrylic acid/methyl methacrylate = | | | |
| | | 31/31/38 (% by mass) | | | |
| | | Mw = 50,000 | | | |
| | Polymerizable | FA-321M (manufactured by Showa Denko Materials co., Ltd.) | 36.20 | 20.20 | 7.40 |
| | compound | BPE-200 (manufactured by Shin-Nakamura Chemical Co., Ltd.) | — | 9.80 | 10.00 |
| | | M-270 (manufactured by Toagosei Co., Ltd.) | 5.00 | — | — |
| | | A-TMPT (manufactured by Shin-Nakamura Chemical Co., Ltd.) | — | 10.00 | 25.00 |
| | Polymerization | 2,2′-bis(2-chlorophenyl)-4,4,5,5′-tetraphenyl-1,2′-biimidazole | 7.00 | 3.00 | 3.80 |
| | initiator | (manufactured by Tokyo Chemical Industry Co., Ltd.) | | | |
| | Sensitizer | 4,4′-bis(diethylamino)benzophenone (manufactured by Tokyo Chemical | 0.50 | 0.50 | 0.30 |
| | | Industry Co., Ltd.) | | | |
| | Chain transfer | Leucocrystal Violet (manufactured by Tokyo Chemical Industry Co., | 0.40 | 0.90 | — |
| | agent | Ltd.) | | | |
| | | N-phenylglycine (manufactured by Tokyo Chemical Industry Co., Ltd.) | 0.20 | — | 1.00 |
| | Colorant | malachite green (manufactured by Tokyo Chemical Industry Co., Ltd.) | — | 0.05 | 0.05 |
| | Rust inhibitor | CBT-1 (manufactured by JOHOKU CHEMICAL CO., LTD.) | 0.10 | 0.14 | 0.05 |
| | Polymerization | TDP-G (manufactured by Kawaguchi Chemical Industry Co., LTD.) | 0.30 | 0.10 | — |
| | inhibitor | 4-tert-butylcatechol (manufactured by DIC Corporation) | — | — | 0.20 |
| | Antioxidant | Phenidone (manufactured by Tokyo Chemical Industry Co., Ltd.) | 0.01 | 0.01 | 0.01 |
| | Surfactant | F-552 (manufactured by DIC Corporation) | 0.29 | 0.30 | 0.19 |

| | | | | |
|---|---|---|---|---|
| | Total (part by mass) | 100.00 | 100.00 | 100.00 |
| Resin pattern | Thickness of resin pattern (μm) | 5.0 | 5.0 | 5.0 |
| | Depth of presence of sodium ion (μm) | 1.0 | 1.3 | 1.6 |
| Evaluation | Scratch resistance | A | A | A |
| | Edge lift | A | A | A |

In Table 3, the unit of the content of the component described in the column of “Photosensitive composition” is part by mass expressed in terms of solid contents.

TABLE 4

| | | | Example | Example |
|---|---|---|---|---|
| | | | 21 | 22 |
| Photosensitive | Polymerizable compound | Monomer having carboxy group | 0.88 | 0.92 |
| composition | | (ARONIX TO-2349, manufactured by Toagosei Co., Ltd.) | | |
| | | A-NOD-N (manufactured by Shin-Nakamura Chemical Co., Ltd.) | 2.45 | 3.30 |
| | | A-DPH (manufactured by Shin-Nakamura Chemical Co., Ltd.) | 2.29 | 3.03 |
| | | KAYARAD R-604 (manufactured by Nippon Kayaku Co., Ltd.) | 2.44 | 3.30 |
| | Polymer | P-2 solution | — | 48.48 |
| | | (solid contents = 36.3% by mass, acid value = | | |
| | | 95 mgKOH/g, Mw = 27,000, Mn = 15,000) | | |
| | | P-1 solution | 34.17 | — |
| | | (solid contents = 36.2% by mass, acid value = | | |
| | | 124 mgKOH/g, Mw = 18,000, Mn = 7,800) | | |
| | Polymerization initiator | 1-(biphenyl-4-yl)-2-methyl-2-morpholinopropan-1-one | 0.44 | 0.27 |
| | | (APi-307, manufactured by Shenzhen UV-ChemTech Co., Ltd.) | | |
| | | Jone | 0.16 | 0.09 |
| | | 2-(dimethylamino)-2-(4-methylbenzyl)-1-(4-morpholinophenyl) butan-1-one | | |
| | | (Irgacure 379EG, manufactured by BASF SE) | | |
| | | 2-hydroxy-4′-(2-hydroxyethoxy)-2-methylpropiophenone | — | — |
| | | (Irgacure 2959, manufactured by BASF SE) | | |
| | Blocked isocyanate | DURANATE SBN-70D (manufactured by Asahi Kasei Corporation) | 0.79 | — |
| | compound | | | |
| | Additive | N-phenylglycine (manufactured by Tokyo Chemical Industry Co., Ltd.) | — | — |
| | | phenothiazine (manufactured by Tokyo Chemical Industry Co., Ltd.) | 0.02 | — |
| | | benzoimidazole (manufactured by Tokyo Chemical Industry Co., Ltd.) | 0.07 | 0.09 |
| | | isonicotinamide (manufactured by Tokyo Chemical Industry Co., Ltd.) | 0.22 | — |
| | | SMA EF-40 (manufactured by TOMOEGAWA CO., LTD.) | — | 0.04 |
| | | MEGAFACE EXP. MFS-578 (manufactured by DIC Corporation) | 0.24 | — |
| | | FTERGENT 710FL (manufactured by NEOS COMPANY LIMITED) | — | 0.09 |
| | Solvent | 1-methoxy-2-propyl acetate | 10.83 | 1.89 |
| | | methyl ethyl ketone | 45.00 | 38.50 |

| | | | |
|---|---|---|---|
| | Total (part by mass) | 100 | 100 |
| Resin pattern | Thickness of resin pattern (μm) | 5.0 | 5.0 |
| | Depth of presence of sodium ion (μm) | 1.3 | 1.5 |
| Evaluation | Scratch resistance | A | A |
| | Edge lift | A | A |

In Table 4, the unit of the content of the component excluding the solvent, described in the column of “Photosensitive composition”, is part by mass expressed in terms of solid contents. The “P-1 solution” in Table 4 means a solution containing the polymer P-1. The “P-2 solution” in Table 4 means a solution containing the polymer P-2.

TABLE 5

| | | | Example | Example | Example |
|---|---|---|---|---|---|
| | | | 23 | 24 | 25 |
| Photosensitive | Polymerizable | 1,9-nonanediol diacrylate | 6.29 | 6.00 | 6.27 |
| composition | compound | (A-NOD-N, manufactured by Shin-Nakamura Chemical Co., Ltd.) | | | |
| | | dipentaerythritol hexa(meth)acrylate | — | 0.60 | — |
| | | (KAYARAD DPHA, manufactured by Nippon Kayaku Co., Ltd.) | | | |
| | Polymer | P-2 solution | 29.10 | 29.10 | — |
| | | (solid contents = 27% by mass, acid value = | | | |
| | | 95 mgKOH/g, Mw = 27,000, Mn 15,000) | | | |
| | | P-3 solution | — | — | 29.05 |
| | | (solid contents = 27% by mass, Mw = 37,000) | | | |
| | Polymerization | 2-(dimethylamino)-2-(4-methylbenzyl)-1-(4-morpholinophenyl) butan-1-one | 0.01 | 0.01 | — |
| | initiator | (Irgacure 379EG, manufactured by BASF SE) | | | |
| | | 1-(biphenyl-4-yl)-2-methyl-2-morpholinopropan-1-one | 0.32 | 0.32 | 0.33 |
| | | (APi-307, manufactured by Shenzhen UV-ChemTech Co., Ltd.) | | | |
| | Additive | 2-naphthalene thiol (manufactured by Tokyo Chemical Industry Co., Ltd.) | 0.015 | 0.003 | 0.003 |
| | Surfactant | MEGAFACE 710FL (manufactured by DIC Corporation, 50% by mass | 0.09 | 0.08 | 0.05 |
| | | PGMEA solution) | | | |
| | Solvent | propylene glycol methyl ether acetate (PGMEA) | 38.61 | 38.55 | 38.62 |
| | | methyl ethyl ketone (MEK) | 25.65 | 25.35 | 25.65 |

| | | | | |
|---|---|---|---|---|
| Resin pattern | Thickness of resin pattern (μm) | 5.0 | 5.0 | 5.0 |
| | Depth of presence of sodium ion (μm) | 1.5 | 1.4 | 1.3 |
| Evaluation | Scratch resistance | A | A | A |
| | Edge lift | A | A | A |

In Table 5, the unit of the content of the component excluding the solvent, described in the column of “Photosensitive composition”, is part by mass expressed in terms of solid contents. The “P-2 solution” in Table 5 means a solution containing the polymer P-2. The “P-3 solution” in Table 5 means a solution containing the polymer P-3.

Tables 2 to 5 show that the scratch resistance of Examples 1 to 25 is excellent and the edge lift of Examples 1 to 25 is reduced as compared with Comparative Examples 1 and 2.

### Examples 1A to 25A

Each transfer film was produced and evaluated in the same manner as in Examples 1 to 25, except that the temporary support and the protective film used in the production of the transfer film were changed to the following materials. The results were the same as in Examples 1 to 25, respectively.
Temporary support: product name “COSMOSHINE (registered trademark) A4160”, manufactured by TOYOBO Co., Ltd., thickness: 50 μm, PET film
Protective film: product name “Alphan (registered trademark) E-210F”, manufactured by Oji F-Tex Co., Ltd., thickness: 50 μm, polypropylene film

### Examples 1B to 25B

Each transfer film was produced and evaluated in the same manner as in Examples 1 to 25, except that the temporary support and the protective film used in the production of the transfer film were changed to the following materials. The results were the same as in Examples 1 to 25, respectively.
Temporary support: product name “COSMOSHINE (registered trademark) A4360”, manufactured by TOYOBO Co., Ltd., thickness: 38 μm, PET film
Protective film: product name “Alphan (registered trademark) FG-201”, manufactured by Oji F-Tex Co., Ltd., thickness: 30 μm, polypropylene film

### Examples 1C to 25C

Each transfer film was produced and evaluated in the same manner as in Examples 1 to 25, except that the temporary support and the protective film used in the production of the transfer film were changed to the following materials. The results were the same as in Examples 1 to 25, respectively.
Temporary support: product name “LUMIRROR (registered trademark) #38-U48”, manufactured by Toray Industries, Inc., thickness: 38 m, PET film
Protective film: product name “Alphan (registered trademark) E-210F”, manufactured by Oji F-Tex Co., Ltd., thickness: 50 m, polypropylene film

### Examples 1D to 25D

Each transfer film was produced and evaluated in the same manner as in Examples 1 to 25, except that the temporary support and the protective film used in the production of the transfer film were changed to the following materials. The results were the same as in Examples 1 to 25, respectively.
Temporary support: product name “LUMIRROR (registered trademark) #25-T60”, manufactured by Toray Industries, Inc., thickness: 25 m, PET film
Protective film: product name “Alphan (registered trademark) FG-201”, manufactured by Oji F-Tex Co., Ltd., thickness: 30 m, polypropylene film

### Examples 1E to 25E

Each transfer film was produced and evaluated in the same manner as in Examples 1 to 25, except that the temporary support and the protective film used in the production of the transfer film were changed to the following materials. The results were the same as in Examples 1 to 25, respectively.
Temporary support: product name “LUMIRROR (registered trademark) 16FB40”, manufactured by Toray Industries, Inc., thickness: 16 μm, PET film
Protective film: product name “Alphan (registered trademark) E-210F”, manufactured by Oji F-Tex Co., Ltd., thickness: 50 μm, polypropylene film

### Examples 101 to 125

(Preparation of Composition Y-1 for Forming Transparent Resin Layer)

A composition Y-1 for forming a transparent resin layer, which had composition described in Table 6, was prepared.

TABLE 6

| Material | | Y-1 |
|---|---|---|
| NanoUse OZ-S30M: ZrO₂ particles (containing tin oxide) | | 4.34 |
| methanol dispersion liquid (non-volatile component: 30.5%) | | |
| manufactured by Nissan Chemical Corporation | | |
| Ammonia water (25%) | | 7.84 |
| Polymer | Copolymer of methacrylic acid/aryl methacrylate | 0.20 |
| | (Mw = 38,000, compositional ratio = 20% by mass/80% by mass) | |
| | ARUFON UC-3920 | 0.02 |
| | (manufactured by Toagosei Co., Ltd.) | |

| | |
|---|---|
| Monomer having carboxy group | 0.03 |
| ARONIX TO-2349 (manufactured by Toagosei Co., Ltd.) | |
| Adenine (manufactured by Tokyo Chemical Industry Co., Ltd.) | 0.03 |
| N-Methyl diethanol amine (manufactured by Tokyo Chemical Industry Co., Ltd.) | 0.03 |
| MEGAFACE F444 (manufactured by DIC Corporation) | 0.01 |
| Ion exchange water | 21.3 |
| Methanol | 66.2 |
| Total (part by mass) | 100 |

(Production of Transfer Film)

A photosensitive layer was formed on a temporary support according to the method described in “Production of transfer film” of Example 1. The composition Y-1 for forming a transparent resin layer was applied onto the photosensitive layer, and then dried to form a transparent resin layer. The applying amount was adjusted so that a thickness after curing was 73 nm. A protective film (LUMIRROR 16KS40, manufactured by Toray Industries, Inc.) was pressure-bonded onto the transparent resin layer to produce a transfer film.

(Production of Laminate)

Each of laminates of Examples 101 to 125 was obtained by the same procedure as in Examples 1 to 25, except that a laminate was produced using the above-described transfer film including a transparent resin layer. That is, except for the transparent resin layer, the production conditions of the laminates of Examples 101 to 125 correspond to the production conditions of the laminates of Examples 1 to 25, respectively. Using the obtained laminates, the “scratch resistance” and “edge lift” described above were evaluated. The evaluation results of Examples 101 to 125 were the same as the evaluation results of Examples 1 to 25, respectively.

### Example 201

Using each of the transfer films of Examples 1 to 17 and 101 to 117, a liquid crystal display device provided with a touch panel was manufactured by the following method.

A substrate on which an ITO transparent electrode pattern and a copper lead wire were formed on cycloolefin polymer film was prepared. Using a transfer film from which the protective film had been peeled off, the transfer film was laminated on the substrate at a position where the transfer film covered the ITO transparent electrode pattern and the copper lead wire. The lamination was performed using a vacuum laminator manufactured by MCK under conditions of a temperature of the cycloolefin polymer film: 40° C., a rubber roller temperature: 100° C., a linear pressure: 3 N/cm, and a transportation speed: 2 m/min. Next, using a proximity type exposure machine (manufactured by Hitachi High-Tech Electronics Engineering Co., Ltd.) including an ultra-high pressure mercury lamp, an exposure mask (quartz exposure mask having a pattern for forming an overcoat) and the temporary support were closely attached and allowed to stand in an environment of 23° C. and 55% RH (relative humidity) for 24 hours, and the photosensitive layer was exposed in a patterned manner with an exposure amount of 150 mJ/cm² (i-rays) through the temporary support. After peeling off the temporary support, a development treatment was performed for 30 seconds using a 1.0% by mass aqueous solution of sodium carbonate at 23° C. The developed sample was washed with water by spraying pure water at 22° C. for 30 seconds from an ultra-high pressure washing nozzle. Subsequently, air was blown to remove water on the sample, and the sample was allowed to stand in an environment of 23° C. and 55% RH (relative humidity) for 24 hours. The resin pattern was exposed with an exposure amount of 1200 mJ/cm² (measured value with i-rays) using a post-exposure machine (manufactured by Ushio, Inc.) having a high pressure mercury lamp (post-exposure). A post-baking treatment was performed at 145° C. for 30 minutes to obtain a laminate including, on the cycloolefin polymer film, the ITO transparent electrode pattern, the copper lead wire, and the resin pattern in this order. Next, using the produced laminate, a touch panel was produced by a known method. The produced touch panel was attached to a liquid crystal display element produced by a method described in paragraphs [0097] to [0119] of JP2009-47936A, thereby producing a liquid crystal display device equipped with a touch panel. It was confirmed that the liquid crystal display device equipped with a touch panel had excellent display properties and operated without problems.

The disclosure of JP2021-058108 filed on Mar. 30, 2021 is incorporated in the present specification by reference.

All documents, patent applications, and technical standards described in the present specification are incorporated herein by reference to the same extent as in a case of being specifically and individually noted that individual documents, patent applications, and technical standards are incorporated by reference.

What is claimed is:

1. A laminate comprising:
a base material; and
a resin pattern,
wherein, in a case where, based on a depth direction analysis of the resin pattern performed along a direction from the resin pattern toward the base material, an intensity of at least one component selected from the group consisting of a sodium ion and a potassium ion, which is detected on a surface of the resin pattern, is defined as 100%, a depth of presence of the at least one component selected from the group consisting of a sodium ion and a potassium ion in the resin pattern is 0.3 μm to 3.0 μm, the depth of presence being defined by a distance from the surface of the resin pattern to a point where the intensity of the at least one component selected from the group consisting of a sodium ion and a potassium ion first reaches 90%.

2. The laminate according to claim 1,
wherein a ratio of the depth of presence to a thickness of the resin pattern is 0.1 to 0.9.

3. The laminate according to claim 1,
wherein the resin pattern is a cured substance of a photosensitive composition.

4. The laminate according to claim 3,
wherein the photosensitive composition contains a polymerizable compound and a polymerization initiator.

5. The laminate according to claim 3,
wherein the photosensitive composition contains a polymer.

6. The laminate according to claim 5,
wherein the polymer has a polymerizable group.

7. The laminate according to any one of claim 1, further comprising:
a transparent electrode between the base material and the resin pattern.

8. The laminate according to any one of claim 1,
wherein the laminate is a touch panel.

9. A manufacturing method of a laminate, comprising, in the following order:
disposing a photosensitive layer on a base material;
exposing the photosensitive layer in a patterned manner;
removing an exposed portion or a non-exposed portion of the photosensitive layer using a developer containing at least one component selected from the group consisting of a sodium ion and a potassium ion to form a resin pattern;
washing the resin pattern with water; and
allowing the base material and the resin pattern to stand,
wherein, in a case where, based on a depth direction analysis of the resin pattern after allowing the base material and the resin pattern to stand, which is performed along a direction from the resin pattern toward the base material, an intensity of at least one component selected from the group consisting of a sodium ion and a potassium ion, which is detected on a surface of the resin pattern, is defined as 100%, a depth of presence of the at least one component selected from the group consisting of a sodium ion and a potassium ion in the resin pattern is 0.3 μm to 3.0 μm, the depth of presence being defined by a distance from the surface of the resin pattern to a point where the intensity of the at least one component selected from the group consisting of a sodium ion and a potassium ion first reaches 90%.
